(19) United States
(12) Patent Application Publication
(10) Pub. No.: US 2024/0233838 A1
(43) Pub. Date: Jul. 11, 2024

(54) SEMICONDUCTOR STORAGE DEVICE

(71) Applicant: Kioxia Corporation, Minato-ku, Tokyo (JP)

(72) Inventors: Yousuke HAGIWARA, Kawasaki Kanagawa (JP); Tomonori KUROSAWA, Zama Kanagawa (JP)

(73) Assignee: Kioxia Corporation, Minato-ku, Tokyo (JP)

(21) Appl. No.: 18/403,944

(22) Filed: Jan. 4, 2024

(30) Foreign Application Priority Data
Jan. 6, 2023 (JP) 2023-001170

(51) Int. Cl. G11C 16/32; G11C 16/04

(52) U.S. Cl. CPC G11C 16/32; G11C 16/0483

(57) ABSTRACT

According to one embodiment, a semiconductor storage device includes a receive unit configured to receive a first toggle signal. The semiconductor storage device includes a comparison circuit configured to generate and output a second toggle signal, wherein the second toggle signal switches based on a relationship of the first toggle signal relative to a reference potential. The semiconductor storage device includes a variable current source connected to the comparison circuit and configured to provide a current output. The semiconductor storage device includes a sequencer configured to adjust the current output from the current source based on an input control signal.

### CROSS-REFERENCE TO RELATED APPLICATION(S)

This application is based upon and claims the benefit of priority from Japanese Patent Application No. 2023-001170, filed Jan. 6, 2023, the entire contents of which are incorporated herein by reference.

### FIELD

Embodiments described herein relate generally to a semiconductor storage device.

### BACKGROUND

For example, a semiconductor storage device such as a NAND flash memory receives write data from a memory controller and stores the data. The data from the memory controller is transmitted to the semiconductor storage device as a toggle signal that switches between different logic levels. The semiconductor storage device determines at which of the levels the toggle signal is based on a magnitude relationship of the toggle signal with respect to a predetermined reference potential.

### DESCRIPTION OF THE DRAWINGS

FIG. 1 is a block diagram illustrating a configuration example of a memory system according to a first embodiment.

FIG. 2 is a block diagram illustrating a configuration example of the memory system.

FIG. 3 is a block diagram illustrating a configuration of the semiconductor storage device.

FIG. 4 is an equivalent circuit diagram illustrating a configuration of a memory cell array.

FIG. 5 is a cross-sectional view illustrating the configuration of the memory cell array.

FIG. 6 is a diagram illustrating a circuit configuration of a sense amplifier unit.

FIG. 7 is a diagram illustrating an example of a threshold voltage distribution of a memory cell transistor.

FIG. 8 is a diagram illustrating a potential change of each wiring during a write operation.

FIG. 9 is a diagram illustrating a potential change of each wiring during a read operation.

FIG. 10 is a diagram illustrating an example of a temporal change in signal and the like transmitted and received between the semiconductor storage device and the memory controller.

FIG. 11 is a diagram illustrating a toggle signal.

FIG. 12 is a diagram illustrating a configuration of an input/output pad group 31 and a configuration of an input/output circuit 21 in the semiconductor storage device.

FIG. 13 is a diagram illustrating a configuration example of a comparison circuit.

FIG. 14 is a diagram illustrating an example of a correction code used to correct a current output from a current source.

FIGS. 15A-15C are a diagram illustrating an example of a toggle signal.

FIGS. 16A-16C are a diagram illustrating an example of a toggle signal.

FIG. 17 is a flowchart illustrating an example of processes executed by the memory controller.

FIG. 18 is a diagram illustrating a correction code setting method.

FIG. 19 is a diagram illustrating a configuration of an input/output pad group 31 and a configuration of an input/output circuit 21 in a semiconductor storage device according to a second embodiment.

FIG. 20 is a diagram illustrating a configuration example of a comparison circuit.

FIG. 21 is a diagram illustrating a configuration of an input/output pad group and a configuration of an input/output circuit in the semiconductor storage device according to a third embodiment.

FIG. 22 is a flowchart illustrating an example of processes executed by the memory controller.

FIG. 23 is a diagram illustrating a correction code setting method.

FIG. 24 is a diagram illustrating an example of a circuit used for setting a reference potential in a semiconductor storage device according to Comparative Example.

### DETAILED DESCRIPTION

Embodiments provide a semiconductor storage device capable of appropriately receiving write data.

In general, according to one embodiment, a semiconductor storage device includes: a receive unit configured to receive a first toggle signal; a comparison circuit configured to generate and output a second toggle signal, wherein the second toggle signal switches based on a relationship of the first toggle signal relative to a reference potential; a variable current source connected to the comparison circuit and configured to provide a current output; and a sequencer configured to adjust the current output from the current source based on an input control signal.

Hereinafter, this embodiment will be described below with reference to the accompanying drawings. In order to facilitate understanding of the description, the same components in each drawing are denoted by the same reference numerals as much as possible, and redundant description will be omitted.

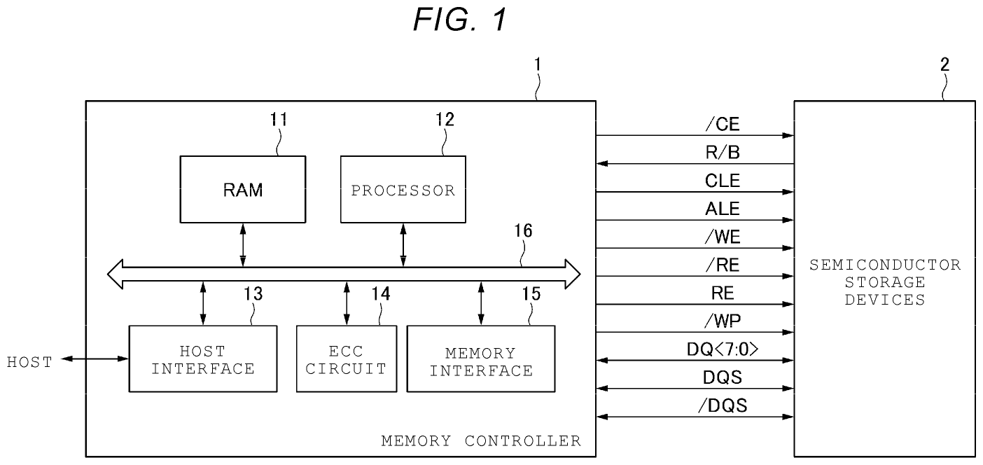

A first embodiment will be described. The semiconductor storage device 2 according to this embodiment is a nonvolatile storage device configured as a NAND flash memory. FIG. 1 illustrates a block diagram of a configuration example of a memory system including a semiconductor storage device 2. This memory system includes a memory controller 1 and the semiconductor storage device 2.

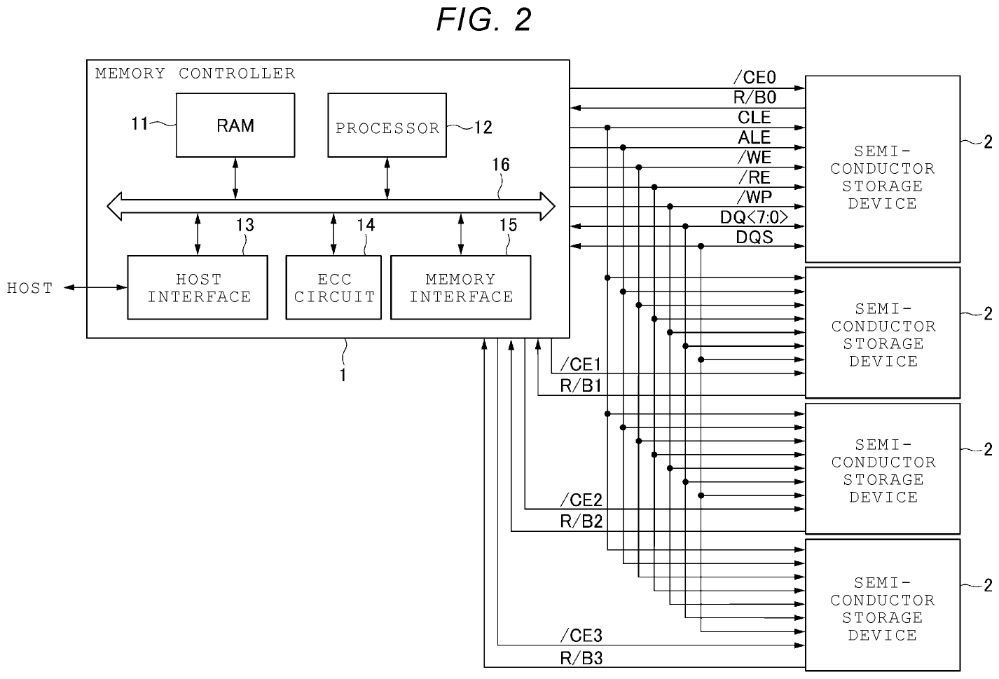

It is noted that in the actual memory system, as illustrated in FIG. 2, a plurality of semiconductor storage devices 2 are provided for one memory controller 1. In FIG. 1, only one of the plurality of semiconductor storage devices 2 is illustrated. A specific configuration of the semiconductor storage device 2 will be described later.

This memory system can be connected to a host (not illustrated). The host is, for example, an electronic device such as a personal computer or a mobile terminal. The memory controller 1 controls writing of data to the semiconductor storage device 2 according to a write request from the host. Furthermore, the memory controller 1 controls reading of data from the semiconductor storage device 2 according to a read request from the host.

Each signal of a chip enable signal /CE, a ready/busy signal R/B, a command latch enable signal CLE, an address latch enable signal ALE, a write enable signal /WE, read enable signals /RE and RE, a write protect signal WP, a signal DQ<7:0> which is data, and data strobe signals DQS and /DQS is transmitted and received between the memory controller 1 and the semiconductor storage device 2.

The chip enable signal /CE is a signal for enabling the semiconductor storage device 2. The ready/busy signal R/B is a signal for indicating whether the semiconductor storage device 2 is in a ready status or a busy status. “The ready status” is a status in which commands from the outside are accepted. “The busy status” is a status in which commands from the outside are not accepted.

As illustrated in FIG. 2, the chip enable signal /CE is individually transmitted to each of the plurality of semiconductor storage devices 2. In FIG. 2, each chip enable signal /CE is attached with the number to the end, for example, “/CE0” so as to be distinguishable from each other.

Similarly, the ready/busy signal R/B is individually transmitted from each of the plurality of semiconductor storage devices 2. In FIG. 2, each ready/busy signal R/B is attached with the number to the end, for example, “R/B0” so as to be distinguishable from each other.

The signals (command latch enable signal CLE and the like) other than the chip enable signal /CE and the ready/busy signal R/B are transmitted and received between the memory controller 1 and the semiconductor storage device 2 via the signal lines that are common to the plurality of semiconductor storage devices 2. The memory controller 1 identifies the semiconductor storage device 2 that becomes a target of communication by using the individual chip enable signal /CE.

The command latch enable signal CLE is a signal indicating that the signal DQ<7:0> is a command. The address latch enable signal ALE is a signal indicating that the signal DQ<7:0> is an address. The write enable signal /WE is a signal for loading the received signal into the semiconductor storage device 2 and is asserted by the memory controller 1 every time the command, the address, and the data are received. The memory controller 1 instructs the semiconductor storage device 2 to load the signal DQ<7:0> while the signal /WE is at “L” level.

The read enable signal /RE is a signal used by memory controller 1 to read data from the semiconductor storage device 2. The signal RE is a complementary signal to the signal /RE. These are used, for example, to control an operation timing of the semiconductor storage device 2 when outputting the signals DQ<7:0>. The write protect signal WP is a signal for instructing semiconductor storage device 2 to prohibit data writing and data erasing. The signal DQ<7:0> is a substance of the data transmitted and received between the semiconductor storage device 2 and the memory controller 1, and includes commands, addresses, and data. The data strobe signal DQS is a signal for controlling input/output timing of the signals DQ<7:0>. The signal /DQS is a complementary signal to the signal DQS.

The memory controller 1 includes a RAM 11, a processor 12, a host interface 13, an ECC circuit 14, and a memory interface 15. The RAM 11, the processor 12, the host interface 13, the ECC circuit 14, and the memory interface 15 are connected to each other by an internal bus 16.

The host interface 13 outputs requests, user data (write data), or the like received from the host to the internal bus 16. In addition, the host interface 13 transmits the user data read from the semiconductor storage device 2, responses from the processor 12, and the like to the host.

The memory interface 15 controls the process of writing the user data and the like to the semiconductor storage device 2 and the process of reading the user data from the semiconductor storage device 2 based on instructions from the processor 12.

The processor 12 controls the memory controller 1 in an integrated manner. The processor 12 is, for example, a CPU or an MPU. When the processor 12 receives the request from the host via the host interface 13, the processor 12 performs control according to the request. For example, the processor 12 instructs the memory interface 15 to write user data and parity to the semiconductor storage device 2 in accordance with the request from the host. In addition, the processor 12 instructs the memory interface 15 to read the user data and the parity from the semiconductor storage device 2 in accordance with the request from the host.

The processor 12 determines the storage area (memory area) on the semiconductor storage device 2 for the user data stored in the RAM 11. The user data is stored in the RAM 11 via the internal bus 16. The processor 12 determines the memory area for (page data) of the data in units of pages, which are units of writing. The user data stored in one page of the semiconductor storage device 2 is also referred to as “a unit data” hereinafter. The unit data is generally encoded and stored as a code word in the semiconductor storage device 2. In this embodiment, the encoding is not essential. Although the memory controller 1 may store the unit data in the semiconductor storage device 2 without encoding the unit data, FIG. 1 illustrates a configuration in which the encoding is performed as an example of the configuration. When the memory controller 1 does not perform the encoding, the page data matches the unit data. In addition, one code word may be generated based on one unit data, or one code word may be generated based on divided data obtained by dividing the unit data. In addition, one code word may be generated by using a plurality of the unit data.

The processor 12 determines the memory area of the semiconductor storage device 2 of the writing destination of the unit data for each unit data. A physical address is allocated to the memory area of the semiconductor storage device 2. The processor 12 manages the memory area of the writing destination of the unit data by using the physical addresses. The processor 12 instructs the memory interface 15 to write the user data to the semiconductor storage device 2 by designating the determined memory area (physical address). The processor 12 manages the correspondence between logical addresses (logical addresses managed by the host) and physical addresses of the user data. When the processor 12 receives the read request including the logical address from the host, the processor 12 identifies the physical address corresponding to the logical address and designates the physical address to instruct the memory interface 15 to read the user data.

The ECC circuit 14 encodes the user data stored in the RAM 11 to generate the code word. In addition, the ECC circuit 14 decodes the code word read from the semiconductor storage device 2. The ECC circuit 14 detects errors in data and corrects the errors by using, for example, a checksum attached to the user data.

The RAM 11 temporarily stores the user data received from the host before storing the user data in the semiconductor storage device 2, and temporarily stores the data read from the semiconductor storage device 2 before transmitting the data to the host. The RAM 11 is, for example, a general-purpose memory such as an SRAM or a DRAM.

FIG. 1 illustrates a configuration example in which the memory controller 1 includes the ECC circuit 14 and the memory interface 15, respectively. However, the ECC circuit 14 may be built in the memory interface 15. In addition, the ECC circuit 14 may be built in the semiconductor storage device 2. The specific configuration and arrangement of each element illustrated in FIG. 1 are not particularly limited.

When the write request is received from the host, the memory system of FIG. 1 operates as follows. The processor 12 allows the RAM 11 to temporarily store data which is a target of a write operation. The processor 12 reads the data stored in the RAM 11 and inputs the data to the ECC circuit 14. The ECC circuit 14 encodes the input data and inputs the code word to the memory interface 15. The memory interface 15 writes the input code word to the semiconductor storage device 2.

When receiving the read request from the host, the memory system of FIG. 1 operates as follows. The memory interface 15 inputs the code word read from the semiconductor storage device 2 to the ECC circuit 14. The ECC circuit 14 decodes the input code word and stores the decoded data in the RAM 11. The processor 12 transmits the data stored in RAM 11 to the host via host interface 13.

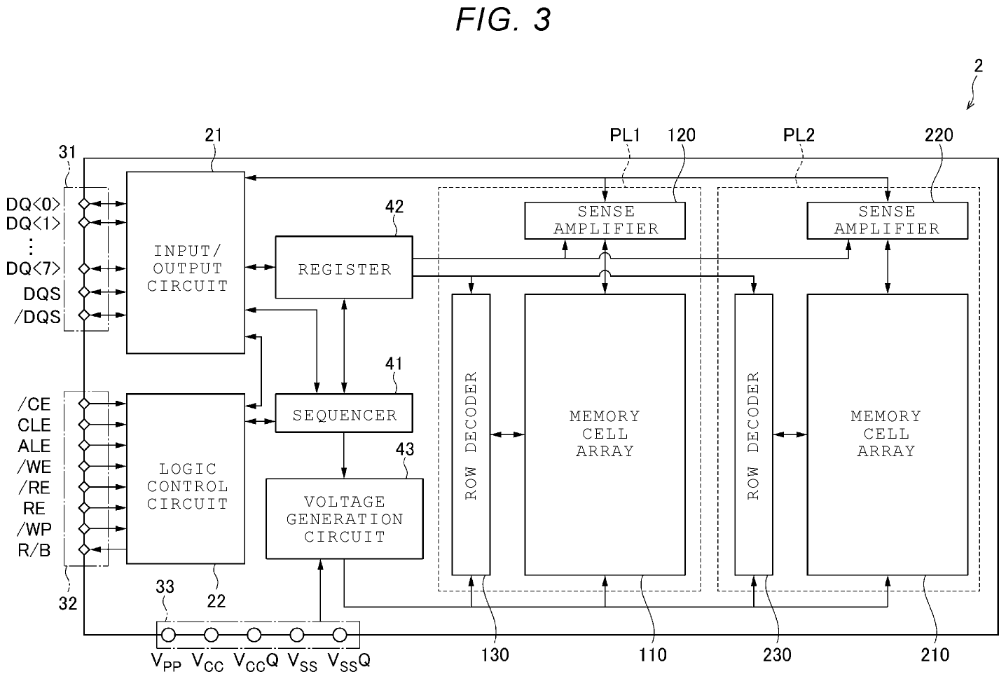

A configuration of the semiconductor storage device 2 will be described. As illustrated in FIG. 3, the semiconductor storage device 2 includes two planes PL1 and PL2, an input/output circuit 21, a logic control circuit 22, a sequencer 41, a register 42, a voltage generation circuit 43, an input/output pad group 31, a logic control pad group 32, and a power input terminal group 33.

The plane PL1 includes a memory cell array 110, a sense amplifier 120, and a row decoder 130. In addition, the plane PL2 includes a memory cell array 210, a sense amplifier 220, and a row decoder 230. A configuration of the plane PL1 and a configuration of the plane PL2 are the same. That is, the configuration of the memory cell array 110 and the configuration of the memory cell array 210 are the same, the configuration of the sense amplifier 120 and the configuration of the sense amplifier 220 are the same, and the configuration of the row decoder 130 and the configuration of the row decoder 230 are the same. The number of planes provided in the semiconductor storage device 2 may be two similarly to this embodiment, but may also be one, or may be three or more.

The memory cell array 110 and the memory cell array 210 are portions that store data. Each of the memory cell array 110 and the memory cell array 210 includes a plurality of memory cell transistors associated with word lines and bit lines. These specific configurations will be described later.

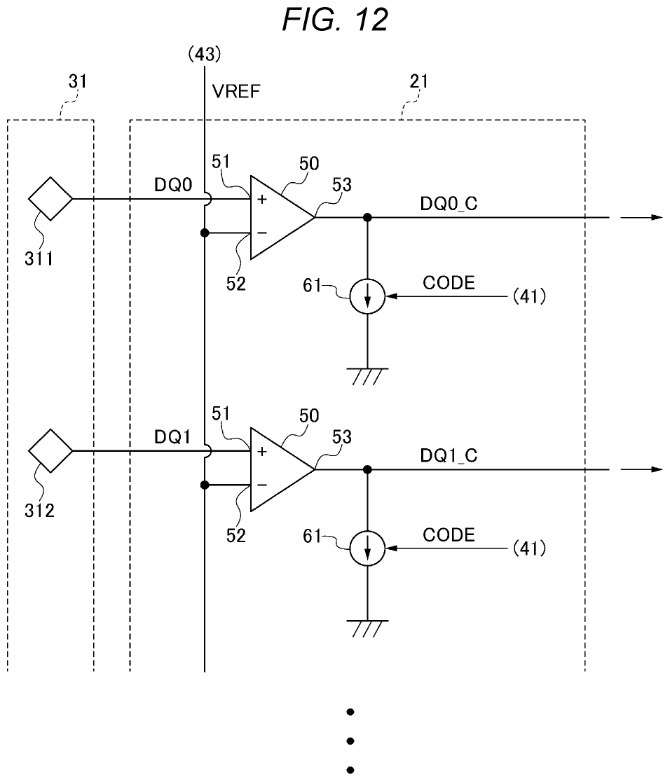

The input/output circuit 21 transmits and receives the signal DQ<7:0> and the data strobe signals DQS and /DQS to and from the memory controller 1. The input/output circuit 21 transfers the command and the address in the signal DQ<7:0> to the register 42. In addition, the input/output circuit 21 transmits and receives the write data and the read data to and from the sense amplifier 120 and the sense amplifier 220. The input/output circuit 21 has both the input circuit into which data, commands, and the like from the memory controller 1 are input and the output circuit which outputs data to the memory controller 1. Among these, the specific configuration of the input circuit will be described later with reference to FIG. 12 and the like.

The logic control circuit 22 receives the chip enable signal /CE, the command latch enable signal CLE, the address latch enable signal ALE, the write enable signal /WE, the read enable signals RE /RE, and the write protect signal /WP from the memory controller 1. In addition, the logic control circuit 22 transfers the ready/busy signal R/B to the memory controller 1 to notify the outside of the status of the semiconductor storage device 2.

Both of the input/output circuit 21 and the logic control circuit 22 are circuits configured as portions through which signals are input/output to/from the memory controller 1. In other words, the input/output circuit 21 and the logic control circuit 22 are provided as interface circuits for the semiconductor storage device 2.

The sequencer 41 controls the operation of each unit such as the planes PL1 and PL2 and the voltage generation circuit 43 based on the control signal input from the memory controller 1 to the semiconductor storage device 2. The sequencer 41 corresponds to a “control unit” that controls the operations of the logic control circuit 22, the memory cell arrays 110 and 210, and other components.

The register 42 is a portion that temporarily latches commands and addresses. The register 42 also stores status information indicating the status of each of the planes PL1 and PL2. The status information is output as a status signal from the input/output circuit 21 to the memory controller 1 according to the request from the memory controller 1.

The voltage generation circuit 43 is a portion that generates respective voltages necessary for the write operation, the read operation, and the erase operation for the data in the memory cell arrays 110 and 210 based on instructions from the sequencer 41. Such voltages include, for example, voltages such as VPGM, VPASS_PGM, and VPASS_READ applied to the word line WL, which will be described later, and voltages applied to the bit line BL, which will be described later. The voltage generation circuit 43 can individually apply a voltage to each of the word line WL, the bit line BL, or the like so that the plane PL1 and the plane PL2 can operate in parallel with each other.

The input/output pad group 31 is a portion provided with a plurality of terminals (pads) for transmitting and receiving signals between the memory controller 1 and the input/output circuit 21. Each terminal is provided individually corresponding to the signal DQ<7:0> and the data strobe signals DQS and /DQS.

The logic control pad group 32 is a portion provided with a plurality of terminals (pads) for transmitting and receiving signals between the memory controller 1 and the logic control circuit 22. The respective terminals are individually provided corresponding to the chip enable signal /CE, the command latch enable signal CLE, the address latch enable signal ALE, the write enable signal /WE, the read enable signals RE and /RE, the write protect signal /WP, and the ready/busy signal R/B.

The power input terminal group 33 is a portion provided with the plurality of terminals for receiving the application of the voltages necessary for the operations of the semiconductor storage device 2. The voltages applied to each terminal include power supply voltages Vcc, VccQ, and Vpp, and ground voltages Vss and VssQ.

The power supply voltage Vcc is a circuit power supply voltage externally applied as an operating power supply for the memory cell array 110 and the like and is, for example, a voltage of about 2.5 V. The ground voltage Vss is a ground voltage used as a reference for the power supply voltage Vcc.

A power supply voltage VccQ is a voltage used when transmitting and receiving the signals DQ<7:0> and the like between the memory controller 1 and the semiconductor storage device 2 and is, for example, a voltage of 1.2 V. A ground voltage VssQ is a ground voltage used as a reference for the power supply voltage VccQ.

The power supply voltage Vpp is a power supply voltage higher than the power supply voltage Vcc and is, for example, a voltage of 12 V. When writing data to or erasing data from the memory cell arrays 110 and 210, a high voltage (VPGM) of about 20 V is required. At this time, boosting the power supply voltage Vpp of approximately 12 V can generate a desired voltage faster in speed and lower in power consumption than boosting the power supply voltage Vcc of approximately 2.5 V by using a booster circuit of the voltage generation circuit 43. On the other hand, for example, when the semiconductor storage device 2 is used in the environment where high voltage cannot be supplied, no voltage may be supplied to the power supply voltage Vpp. Even when power supply voltage Vpp is not supplied, the semiconductor storage device 2 can perform various operations as long as a power supply voltage Vcc is supplied. That is, the power supply voltage Vcc is a power supply that is standardly supplied to the semiconductor storage device 2, and the power supply voltage Vpp is a power supply that is additionally and feely-selected supplied according to, for example, the usage environment.

The configurations of the planes PL1 and PL2 will be described. It is noted that, as described above, the configuration of the plane PL1 and the configuration of the plane PL2 are the same. For this reason, only the configuration of the plane PL1 will be described below, and illustration and description of the configuration of the plane PL2 will be omitted.

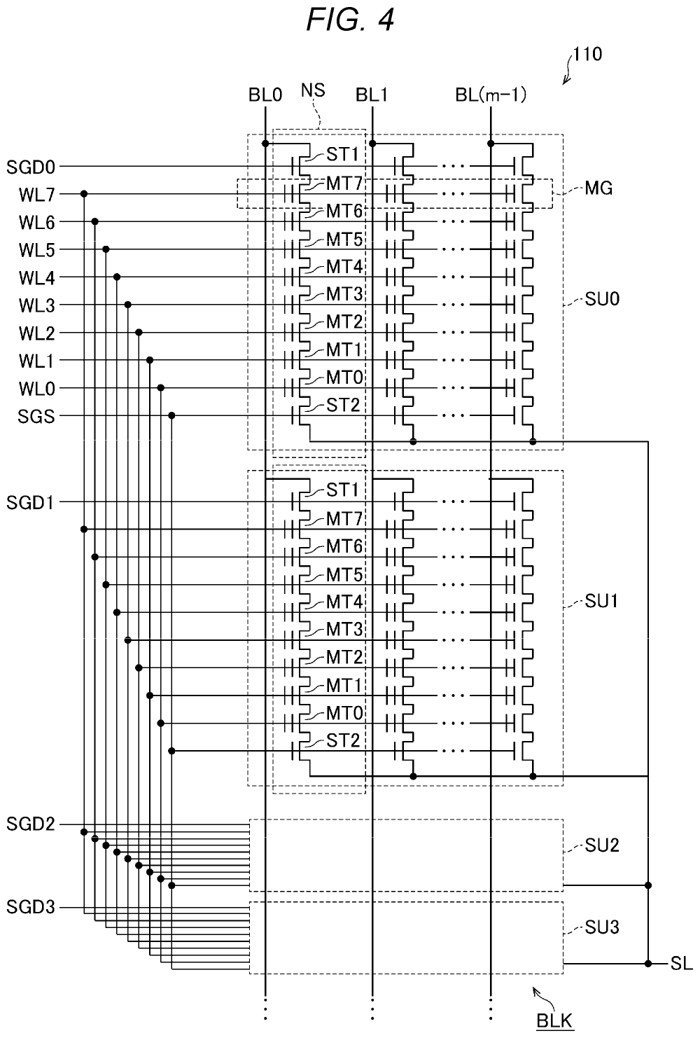

FIG. 4 illustrates the configuration of the memory cell array 110 provided in the plane PL1 as an equivalent circuit diagram. Although the memory cell array 110 is configured with a plurality of blocks BLK, only one of these blocks BLK is illustrated in FIG. 4. The configurations of other blocks BLK provided in the memory cell array 110 are also the same as those illustrated in FIG. 4.

As illustrated in FIG. 4, the block BLK includes, for example, four string units SU (SU0 to SU3). In addition, each string unit SU includes a plurality of NAND strings NS. Each NAND string NS includes, for example, eight memory cell transistors MT (MT0 to MT7) and select transistors ST1 and ST2.

It is noted that the number of memory cell transistors MT is not limited to eight, and may be, for example, 32, 48, 64, or 96. For example, in order to improve cutoff characteristics, each of the select transistors ST1 and ST2 may be configured with a plurality of transistors instead of a single transistor. Furthermore, a dummy cell transistor may be provided between the memory cell transistor MT and the select transistors ST1 and ST2.

The memory cell transistor MT is disposed to be connected in series between the select transistor ST1 and the select transistor ST2. The memory cell transistor MT7 at one end thereof is connected to the source of the select transistor ST1, and the memory cell transistor MT0 at the other end thereof is connected to the drain of the select transistor ST2.

The gates of the select transistors ST1 of the respective string units SU0 to SU3 are commonly connected to select gate lines SGD0 to SGD3, respectively. The gates of the select transistors ST2 are commonly connected to the same select gate line SGS among the plurality of string units SU in the same block BLK. The gates of the memory cell transistors MT0 to MT7 in the same block BLK are commonly connected to word lines WL0 to WL7, respectively. That is, the word lines WL0 to WL7 and the select gate line SGS are common to the plurality of string units SU0 to SU3 within the same block BLK, whereas the select gate lines SGD are provided individually for each of the plurality of string units SU0 to SU3 within the same block BLK.

The memory cell array 110 is provided with m bit lines BL (BL0, BL1, . . . , BL(m−1)). The above-mentioned “m” is an integer indicating the number of NAND strings NS provided in one string unit SU. In each NAND string NS, the drain of the select transistor ST1 is connected to the corresponding bit line BL. The source of the select transistor ST2 is connected to the source line SL. The source line SL is commonly connected to the sources of the plurality of select transistors ST2 provided in the block BLK.

The data stored in the plurality of memory cell transistors MT in the same block BLK is erased all at once. On the other hand, reading and writing of data are performed all at once on the plurality of memory cell transistors MT connected to one word line WL and belonging to one string unit SU. Each memory cell can store 3-bit data including the upper bit, the middle bit, and the lower bit.

That is, the semiconductor storage device 2 according to this embodiment employs a TLC method in which 3-bit data is stored in one memory cell transistor MT as a method for writing data into the memory cell transistor MT. Instead of this aspect, as a method for writing data into the memory cell transistor MT, an MLC method or the like of storing 2-bit data in one memory cell transistor MT may be adopted. The number of bits of data stored in one memory cell transistor MT is not particularly limited.

It is noted that, in the following description, a set of 1-bit data stored in the plurality of memory cell transistors MT connected to one word line WL and belonging to one string unit SU will be referred to as “a page”. In FIG. 4, one of the sets including the plurality of memory cell transistors MT as described above is attached with symbol “MG”.

When 3 bits of data are stored in one memory cell transistor MT similarly to this embodiment, a set of the plurality of memory cell transistors MT connected to the common word line WL in one string unit SU can store three pages of data. Among these, the page including a set of the lower bit data is hereinafter also referred to as “a lower page”, and the data of the lower page is also hereinafter referred to as “lower page data”. Similarly, the page including a set of the middle bit data is also referred to below as “a middle page,” and the data on the middle page is also referred to below as “middle page data.” The page including a set of the upper bit data is also referred to below as “an upper page”, and the data on the upper page is also referred to below as “upper page data”.

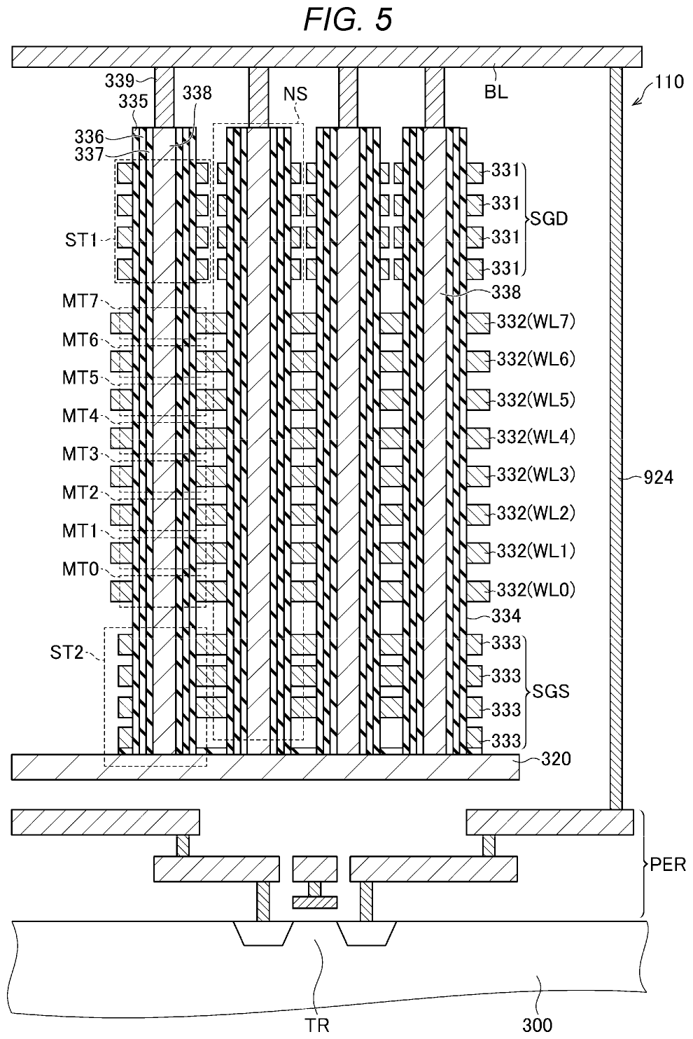

FIG. 5 illustrates a configuration of the memory cell array 110 and its surroundings as a schematic cross-sectional view. As illustrated in the figure, in the memory cell array 110, the plurality of NAND strings NS are formed on a conductor layer 320. The conductor layer 320 is also referred to as a buried source line (BSL) and corresponds to the source line SL in FIG. 4.

A plurality of wiring layers 333 functioning as the select gate lines SGS, a plurality of wiring layers 332 functioning as word lines WL, and a plurality of wiring layers 331 functioning as the select gate lines SGD are stacked above the conductor layer 320. An insulating layer (not illustrated) is disposed among the respective stacked wiring layers 333, 332, and 331.

A plurality of memory holes 334 are formed in the memory cell array 110. The memory hole 334 is a hole that vertically penetrates the wiring layers 333, 332, and 331 and insulating layer (not illustrated) among these wiring layers and reaches the conductive layer 320. A block insulating film 335, a charge storage layer 336, and a gate insulating film 337 are sequentially formed on the side surface of the memory hole 334, and conductor pillars 338 are buried inside thereof. The conductor pillar 338 is made of, for example, polysilicon and functions as an area where the channel is formed during the operation of the memory cell transistor MT and the select transistors ST1 and ST2 provided in the NAND string NS. In this manner, a columnar body including the block insulating film 335, the charge storage layer 336, the gate insulating film 337, and the conductor pillar 338 is formed inside the memory hole 334.

Among the columnar bodies formed inside the memory hole 334, each portion that intersects each of the stacked wiring layers 333, 332, and 331 functions as a transistor. Among these plurality of transistors, those located at the portions intersecting the wiring layer 331 function as a select transistors ST1. Among the plurality of transistors, those located at the portions intersecting the wiring layer 332 function as a memory cell transistors MT (MT0 to MT7). Among the plurality of transistors, those located at the portions intersecting the wiring layer 333 function as a select transistors ST2. With this configuration, each of the columnar bodies formed inside each memory hole 334 functions as the NAND string NS described with reference to FIG. 4. The conductor pillar 338 inside the columnar body is a portion that functions as a channel of the memory cell transistor MT and the select transistors ST1 and ST2.

The wiring layer functioning as a bit line BL is formed above the conductor pillar 338. A contact plug 339 connected the conductor pillar 338 and the bit line BL is formed at the upper end of the conductor pillar 338.

The plurality of configurations similar to the configuration illustrated in FIG. 5 are disposed along the depth direction of the paper surface of FIG. 5. One string unit SU is formed by a set of the plurality of NAND strings NS aligned in a row along the depth direction of the page of FIG. 5.

In the semiconductor storage device 2 according to this embodiment, a peripheral circuit PER is provided below the memory cell array 110, that is, at the position between the memory cell array 110 and a semiconductor substrate 300. The peripheral circuit PER is a circuit provided to implement the data write operations, the data read operations, the data erase operations, or the like in the memory cell array 110. The sense amplifier 120, the row decoder 130, the voltage generation circuit 43, and the like illustrated in FIG. 3 are a portion of the peripheral circuit PER. The peripheral circuit PER includes various transistors, RC circuits, and the like. In the example illustrated in FIG. 5, a transistor TR formed on the semiconductor substrate 300 and the bit line BL located above the memory cell array 110 are electrically connected via a contact 924.

It is noted that, instead of this configuration, the configuration in which the memory cell array 110 is directly provided on the semiconductor substrate 300 may be used. In this case, the p-type well area of the semiconductor substrate 300 will function as a source line SL. In addition, the peripheral circuit PER is provided at a position adjacent to the memory cell array 110 along the surface of the semiconductor substrate 300.

Returning to FIG. 3, the explanation will be continued. As described above, in addition to the memory cell array 110 described above, the sense amplifier 120 and the row decoder 130 are provided in the plane PL1.

The sense amplifier 120 is a circuit for adjusting the voltage applied to the bit line BL and converting the voltage of the bit line BL into the read data. When reading the data, the sense amplifier 120 acquires the read data read from the memory cell transistor MT to the bit line BL and transfers the acquired read data to the input/output circuit 21. When writing data, the sense amplifier 120 transfers the write data written via the bit line BL to the memory cell transistor MT.

The row decoder 130 is a circuit configured as a switch group (not illustrated) for applying a voltage to each word line WL. The row decoder 130 receives a block address and row address from the register 42, selects the corresponding block BLK based on the block address, and selects the corresponding word line WL based on the row address. The row decoder 130 switches the opening and the closing of the above-mentioned switch group so that the voltage from the voltage generation circuit 43 is applied to the selected word line WL.

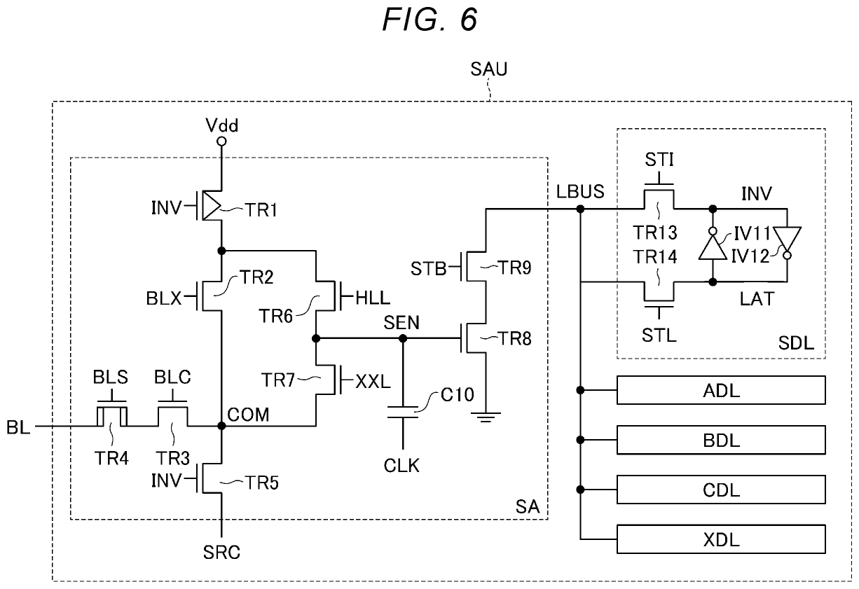

FIG. 6 illustrates a configuration example of the sense amplifier 120. The sense amplifier 120 includes a plurality of sense amplifier units SAU associated with the respective plurality of bit lines BL. FIG. 6 illustrates a detailed circuit configuration of one of these sense amplifier units SAU.

As illustrated in FIG. 6, the sense amplifier unit SAU includes a sense amplifier unit SA and latch circuits SDL, ADL, BDL, CDL, and XDL. The sense amplifier unit SA and the latch circuits SDL, ADL, BDL, CDL, and XDL are connected by a bus LBUS so that these components can transmit and receive data to and from each other.

For example, in the read operation, the sense amplifier unit SA senses the data read to the corresponding bit line BL and determines whether the read data is “0” or “1”. The sense amplifier unit SA includes, for example, a transistor TR1 which is a p-channel MOS transistor, transistors TR2 to TR9 which are n-channel MOS transistors, and capacitor C10.

One end of the transistor TR1 is connected to a power supply line, and the other end of the transistor TR1 is connected to the transistor TR2. The gate of the transistor TR1 is connected to a node INV in the latch circuit SDL. One end of the transistor TR2 is connected to the transistor TR1, and the other end of the transistor TR2 is connected to the node COM. A signal BLX is input to the gate of the transistor TR2. One end of the transistor TR3 is connected to the node COM, and the other end of the transistor TR3 is connected to the transistor TR4. A signal BLC is input to the gate of the transistor TR3. The transistor TR4 is a high voltage MOS transistor. One end of the transistor TR4 is connected to the transistor TR3. The other end of the transistor TR4 is connected to the corresponding bit line BL. A signal BLS is input to the gate of the transistor TR4.

One end of the transistor TR5 is connected to the node COM, and the other end of the transistor TR5 is connected to a node SRC. The gate of transistor TR5 is connected to the node INV. One end of the transistor TR6 is connected between the transistor TR1 and the transistor TR2, and the other end of the transistor TR6 is connected to a node SEN. A signal HLL is input to the gate of the transistor TR6. One end of the transistor TR7 is connected to the node SEN, and the other end of the transistor TR7 is connected to the node COM. A signal XXL is input to the gate of the transistor TR7.

One end of the transistor TR8 is grounded, and the other end of the transistor TR8 is connected to the transistor TR9. The gate of transistor TR8 is connected to the node SEN. One end of the transistor TR9 is connected to the transistor TR8, and the other end of the transistor TR9 is connected to the bus LBUS. A signal STB is input to the gate of the transistor TR9. One end of capacitor C10 is connected to the node SEN. A clock CLK is input to the other end of the capacitor C10.

The signals BLX, BLC, BLS, HLL, XXL, and STB are generated by, for example, the sequencer 41. In addition, the voltage Vdd which is, for example, an internal power supply voltage of the semiconductor storage device 2 is applied to the power supply line connected to one end of the transistor TR1, and the voltage Vss which is, for example, the ground voltage of the semiconductor storage device 2 is applied to the node SRC.

The latch circuits SDL, ADL, BDL, CDL, and XDL temporarily store the read data. The latch circuit XDL is connected to the input/output circuit 21 and is used for inputting/outputting the data between the sense amplifier unit SAU and the input/output circuit 21. The read data is stored in the latch circuit XDL, and thus, is in a state capable of being output from the input/output circuit 21 to the memory controller 1. For example, the data read by the sense amplifier unit SAU is stored in any one of the latch circuits ADL, BDL, and CDL, and after that, transferred to the latch circuit XDL, and output from the latch circuit XDL to the input/output circuit 21. In addition, for example, the data input from the memory controller 1 to the input/output circuit 21 is transferred from the input/output circuit 21 to the latch circuit XDL and is transferred from the latch circuit XDL to one of the latch circuits ADL, BDL, and CDL.

The latch circuit SDL includes, for example, inverters IV11 and IV12, and transistors TR13 and TR14, which are n-channel MOS transistors. The input node of the inverter IV11 is connected to a node LAT. The output node of the inverter IV11 is connected to the node INV. The input node of the inverter IV12 is connected to the node INV. The output node of inverter IV12 is connected to the node LAT. One end of the transistor TR13 is connected to the node INV, and the other end of the transistor TR13 is connected to the bus LBUS. A signal STI is input to the gate of the transistor TR13. One end of the transistor TR13 is connected to the node LAT, and the other end of the transistor TR14 is connected to the bus LBUS. A signal STL is input to the gate of the transistor TR14. For example, the data stored in the node LAT corresponds to the data stored in the latch circuit SDL. In addition, the data stored in the node INV corresponds to the inverted data of the data stored in the node LAT. The circuit configurations of the latch circuits ADL, BDL, CDL, and XDL are similar to, for example, the circuit configuration of the latch circuit SDL, and therefore the description thereof will be omitted.

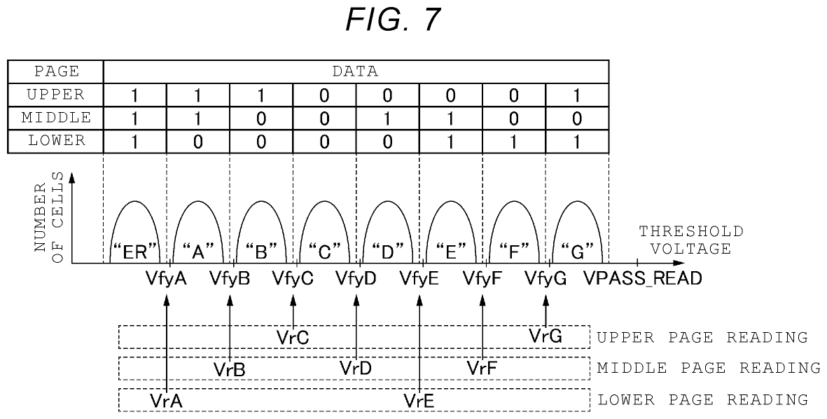

FIG. 7 is a diagram schematically illustrating the threshold voltage distribution and the like of the memory cell transistor MT. The diagram in the middle of FIG. 7 illustrates the corresponding relationship between a threshold voltage of the memory cell transistor MT (horizontal axis) and the number of memory cell transistors MT (vertical axis).

When the TLC method is adopted similarly to this embodiment, the plurality of memory cell transistors MT form eight threshold voltage distributions, as illustrated in the middle portion of FIG. 7. These eight threshold voltage distributions (write levels) are referred to, sequentially, as an “ER” level, an “A” level, a “B” level, a “C” level, a “D” level, an “E” level, an “F” level, and a “G” level from the lowest threshold voltage.

The table in the upper portion of FIG. 7 illustrates examples of the data allocated correspondingly to each of the above-mentioned levels of the threshold voltage. As illustrated in the table, for example, different 3-bit data as illustrated below are allocated to the “ER” level, the “A” level, the “B” level, the “C” level, the “D” level, the “E” level, the “F” level, and the “G” level.
“ER” level: “111” (“lower bit/middle bit/upper bit”)
“A” level: “011”
“B” level: “001”
“C” level: “000”
“D” level: “010”
“E” level: “110”
“F” level: “100”
“G” level: “101”

In this manner, the threshold voltage of the memory cell transistor MT in this embodiment can take one of eight candidate levels set in advance, and the data can be allocated as described above, corresponding to each candidate level.

A verify voltage used in the write operation is set during the pair of threshold voltage distributions adjacent to each other. Specifically, the verify voltages VfyA, VfyB, VfyC, VfyD, VfyE, VfyF, and VfyG are set corresponding to the “A” level, the “B” level, the “C” level, the “D” level, the “E” level, the “F” level, and the “G” level.

The verify voltage VfyA is set between a maximum threshold voltage in the “ER” level and a minimum threshold voltage in the “A” level. When the verify voltage VfyA is applied to the word line WL, among the memory cell transistors MT connected to the word line WL, the memory cell transistor MT of which the threshold voltage is provided in the “ER” level enters an on state, and the Memory cell transistor MT of which the threshold voltages are provided in the threshold voltage distribution of the “A” level or higher enters an off state.

Other verify voltages VfyB, VfyC, VfyD, VfyE, VfyF, and VfyG are also set similarly to the above-described verify voltage VfyA. The verify voltage VfyB is set between the “A” level and the “B” level, the verify voltage VfyC is set between the “B” level and the “C” level, the verify voltage VfyD is set between the “C” level and the “D” level, the verify voltage VfyE is set between the “D” level and the “E” level, the verify voltage VfyF is set between the “E” level and the “F” level, and the verify voltage VfyG is set between the “F” level and the “G” level.

For example, the verify voltage VfyA may be set to 0.8 V, the verify voltage VfyB may be set to 1.6 V, the verify voltage VfyC may be set to 2.4 V, the verify voltage VfyD may be set to 3.1 V, the verify voltage VfyE may be set to 3.8 V, the verify voltage VfyF may be set to 4.6 V, and the verify voltage VfyG may be set to 5.6 V, respectively. However, this invention is not limited thereto, and the verify voltages VfyA, VfyB, VfyC, VfyD, VfyE, VfyF, and VfyG may be set stepwise as appropriate within the range of, for example, 0 V to 7.0 V.

Furthermore, read voltages used in the read operations are set between adjacent threshold voltage distributions. “The read voltage” is a voltage applied to the word line WL connected to the memory cell transistor MT, which is a reading target, that is, the selected word line, during the read operation. In the read operation, data is determined based on the determination result of whether the threshold voltage of the memory cell transistor MT that is a reading target is higher than the applied read voltage.

As schematically illustrated in the diagram of the lower portion of FIG. 7, specifically, the read voltage VrA for determining whether the threshold voltage of the memory cell transistor MT is provided in the “ER” level or equal to or higher than the “A” level is set between the maximum threshold voltage in the “ER” level and the minimum threshold voltage in the “A” level.

The other read voltages VrB, VrC, VrD, VrE, VrF, and VrG are also set similarly to the above-described read voltage VrA. The read voltage VrB is set between the “A” level and the “B” level, the read voltage VrC is set between the “B” level and the “C” level, and read voltage VrD is set between the “C” level and the “D” level, the read voltage VrE is set between the “D” level and the “E” level, the read voltage VrF is set between the “E” level and the “F” level, and the read voltage VrG is set between the “F” level and the “G” level.

Then, the read pass voltage VPASS_READ is set to the voltage higher than the maximum threshold voltage of the highest threshold voltage distribution (for example, the “G” level). The memory cell transistor MT to which the read pass voltage VPASS_READ is applied to the gate enters an on state regardless of the data to be stored.

It is noted that the verify voltages VfyA, VfyB, VfyC, VfyD, VfyE, VfyF, and VfyG are set to be voltages higher than, for example, the read voltages VrA, VrB, VrC, VrD, VrE, VrF, and VrG, respectively. In other words, the verify voltages VfyA, VfyB, VfyC, VfyD, VfyE, VfyF, and VfyG are set to be near the lower tails of the threshold voltage distribution of the “A” level, the “B” level, the “C” level, the “D” level, the “E” level, the “F” level, and the “G” level, respectively.

When the data allocation as described above is applied, one page data (lower page data) of the lower bits in the read operation can be determined by the read result using the read voltages VrA and VrE. One page data (middle page data) of the middle bits can be determined by the read result using the read voltages VrB, VrD, and VrF. One page data (upper page data) of the upper bits can be determined by the read result using the read voltages VrC and VrG. In this manner, since the lower page data, the middle page data, and the upper page data are determined by two, three, and two read operations, respectively, the above-described data allocation is referred to as “a 2-3-2 code”.

It is noted that the data allocation as described above is only an example, and actual data allocation is not limited thereto. For example, 2 bits or 4 bits or more of data may be stored in one memory cell transistor MT. In addition, the number of threshold voltage distributions to which data is allocated (that is, the number of “candidate levels” described above) may be 7 or less, or may be 9 or more. For example, instead of “a 2-3-2 code”, “a 1-3-3 code” or “a 1-2-4 code” may be used. Furthermore, for example, the allocation of lower bits/middle bits/upper bits may be changed. More specifically, for example, in “the 2-3-2 code”, data may be allocated so that the lower page data is determined by the read result using the read voltages VrC and VrB, the middle page data is determined by the read result using the read voltages VrB, VrD, and VrF, and the upper page data is determined by the read result using the read voltages VrA and VrE. That is, for example, the allocation of the lower bits and the allocation of the upper bits may be interchanged. In this case, the data are allocated as follows, corresponding to each level of the threshold voltages.
“ER” level: “111” (“lower bit/middle bit/upper bit”)
“A” level: “110”
“B” level: “100”
“C” level: “000”
“D” level: “010”
“E” level: “011”
“F” level: “001”
“G” level: “101”

The write operation performed in the semiconductor storage device 2 will be described. In the write operation, a program operation and a verify operation are performed. “The program operation” is an operation of changing the threshold voltage of a portion of the memory cell transistors MT by injecting electrons into the charge storage layer 336 of the memory cell transistors MT. “The verify operation” is an operation for determining and verifying whether the threshold voltage of the memory cell transistor MT reaches the target level by reading the data after the above-described program operation. The memory cell transistor MT of which threshold voltage has reached the target level is then prohibited from being written. “The target level” mentioned herein is a specific candidate level set as a target level among the eight candidate levels mentioned above.

In the write operation, the program operation and the verify operation described above are repeatedly executed. Accordingly, the threshold voltage of memory cell transistor MT rises up to the target level.

Among the plurality of word lines WL, the word line WL connected to the memory cell transistor MT, which is target of the write operation (that is, the target of changing the threshold voltage), is also referred to as “a selected word line” hereinafter. In addition, the word line WL connected to the memory cell transistor MT that is not a target of the write operation is also referred to as an “non-selected word line” hereinafter. The memory cell transistor MT, which is target of the write operation, is hereinafter also referred to as “a selected memory transistor.”

Among the plurality of string units SU, the string unit SU, which is target of the write operation, is also referred to as “a selected string unit” hereinafter. In addition, the string unit SU that is not a target of the write operation is also referred to as “an non-selected string unit” hereinafter.

The conductor pillars 338 of each NAND string NS provided in the selected string unit, that is, each channel in the selected string unit is also referred to as “a selected channel” hereinafter. Furthermore, the conductor pillars 338 of each NAND string NS provided in the non-selected string unit, that is, each channel in the non-selected string unit, is also referred to as “a non-selected channel” hereinafter.

Among the plurality of bit lines BL, the bit line BL connected to the selected memory transistor is also referred to as “a selected bit line” hereinafter. Furthermore, the bit line BL that is not connected to the selected memory transistor is also referred to as “a non-selected bit line” hereinafter.

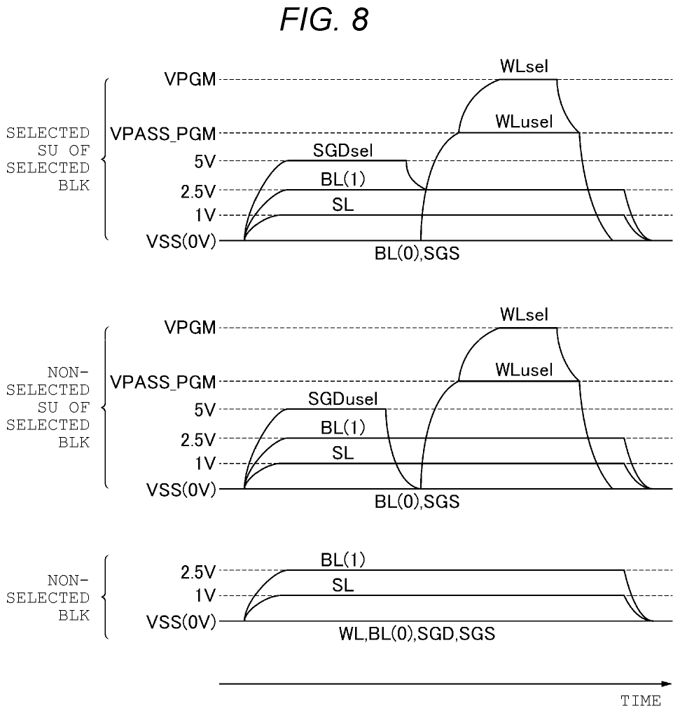

The program operation will be described. In the following, although the example is described in which the target of the program operation is the plane PL1, but the case of the plane PL2 is also similar to the following. FIG. 8 illustrates a potential change of each wiring during the program operation. In the program operation, the sense amplifier 120 changes the potential of each bit line BL in accordance with the program data. For example, the ground voltage Vss (0 V) is applied as a “L” level to the bit line BL connected to the memory cell transistor MT, which is target of the program operation (threshold voltage needs to be increased). For example, 2.5 V is applied as a “H” level to the bit line BL connected to the memory cell transistor MT which is not a program operation (threshold voltage needs to be maintained). The former bit line BL is indicated as “BL(0)” in FIG. 8. The latter bit line BL is indicated as “BL(1)” in FIG. 8.

The row decoder 130 selects any one of the blocks BLK as a target of the write operation, and further selects any one of the string units SU. More specifically, for example, 5 V is applied from the voltage generation circuit 43 via the row decoder 130 to the select gate line SGD (selected select gate line SGDsel) in the selected string unit SU. Accordingly, the select transistor ST1 enters an on state. On the other hand, for example, the voltage Vss is applied to the select gate line SGS from the voltage generation circuit 43 via the row decoder 130. Accordingly, the select transistor ST2 enters an off state.

Furthermore, for example, the voltage of 5 V is applied from the voltage generation circuit 43 via the row decoder 130 to the select gate line SGD (non-selected select gate line SGDusel) of the non-selected string unit SU in the selected block BLK. Accordingly, the select transistor ST1 enters an on state. It is noted that the select gate lines SGS are commonly connected in the string units SU provided in each block BLK. Therefore, even in the non-selected string unit SU, the select transistor ST2 enters an off state.

Furthermore, for example, the voltage Vss is applied from the voltage generation circuit 43 to the select gate line SGD and the select gate line SGS in the non-selected block BLK via the row decoder 130. Accordingly, the select transistor ST1 and the select transistor ST2 enter an off state.

The source line SL is set to a potential higher than a potential of the select gate line SGS. The potential is, for example, 1 V.

Thereafter, the potential of the selected select gate line SGDsel in the selected block BLK is set to, for example, 2.5 V. At this potential, the select transistor ST1 corresponding to the bit line BL(0) to which 0 V is applied in the above-described example is allowed to become on, but at this potential, the select transistor ST1 corresponding to the bit line BL(1) to which 2.5 V is applied is allowed to become off. Accordingly, in the selected string unit SU, the select transistor ST1 corresponding to the bit line BL(0) turns on, and the select transistor ST1 corresponding to the bit line BL(1) to which 2.5 V is applied becomes cut off. On the other hand, the potential of the non-selected select gate line SGDusel is set to, for example, a voltage Vss. Accordingly, in the non-selected string unit SU, the select transistor ST1 becomes cut off regardless of the potentials of the bit line BL(0) and bit line BL(1).

The row decoder 130 then selects any one of the word lines WL in the selected block BLK as a target of the write operation. For example, a voltage VPGM is applied from the voltage generation circuit 43 to the word line WL (selected word line WLsel), which is target of the write operation via the row decoder 130. On the other hand, for example, a voltage VPASS_PGM is applied from the voltage generation circuit 43 to the other word lines WL (non-selected word lines WLusel) via the row decoder 130. The voltage VPGM is a high voltage for injecting electrons into the charge storage layer 336 by a tunneling effect. The voltage VPASS_PGM is a voltage that turns on the memory cell transistor MT connected to the word line WL and is a voltage of not changing a constant threshold voltage. The VPGM is a voltage higher than VPASS_PGM.

In the NAND string NS corresponding to the bit line BL(0), which is the target of the program operation, the select transistor ST1 enters an on state. For this reason, the channel potential of the memory cell transistor MT connected to the selected word line WLsel becomes 0 V. The potential difference between the control gate and the channel increases, and as a result, electrons are injected into the charge storage layer 336, so that the threshold voltage of the memory cell transistor MT rises.

In the NAND string NS corresponding to the bit line BL(1) which is not a target of the program operation, the select transistor ST1 is in a cut-off status. For this reason, the channel of the memory cell transistor MT connected to the selected word line WLsel becomes electrically floating, and thus the channel potential raises near the voltage VPGM due to a capacitive coupling with the word line WL and the like. The potential difference between the control gate and the channel is reduced, and as a result, no electrons are injected into the charge storage layer 336, so that the threshold voltage of the memory cell transistor MT is maintained. To be exact, the threshold voltage does not change to the extent that a threshold voltage distribution level transitions to the higher distribution.

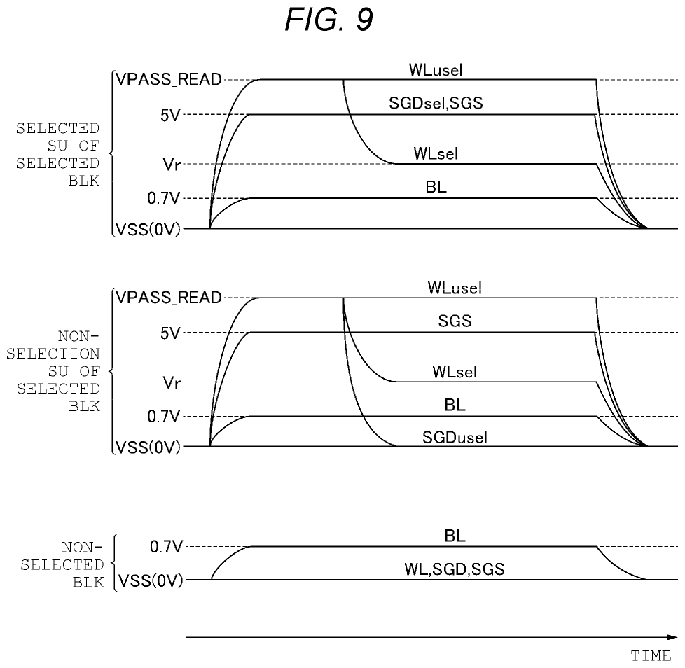

The read operation will be described. In the following, although the example will be described in which the target of the read operation is the plane PL1, the case of the plane PL2 is also similar to the following. The verify operation performed following the program operation is the same as the read operation described hereinafter. FIG. 9 illustrates a potential change of each wiring during the read operation. In the read operation, the NAND string NS including the memory cell transistor MT, which is a target of the read operation, is selected. Alternatively, the string unit SU containing the page, which is a target of the read operation, is selected.

First, for example, 5 V is applied from the voltage generation circuit 43 to the selected select gate line SGDsel, the non-selected select gate line SGDusel, and the select gate line SGS via the row decoder 130. Accordingly, the select transistor ST1 and the select transistor ST2 provided in the selection block BLK enter an on state. Furthermore, for example, the read pass voltage VPASS_READ is applied from the voltage generation circuit 43 to the selected word line WLsel and the non-selected word lines via the row decoder 130. The read pass voltage VPASS_READ is a voltage that can turn on the memory cell transistor MT regardless of the threshold voltage of the memory cell transistor MT and does not change the threshold voltage. Accordingly, the current is electrically connected in all the NAND strings NS provided in the selected block BLK regardless of whether to be the selected string units SU or the non-selected string units SU.

Next, the read voltage Vr such as VrA is applied from the voltage generation circuit 43 to the word line WL (selected word line WLsel) connected to the memory cell transistor MT, which is the target of the read operation, via the row decoder 130. The read pass voltage VPASS_READ is applied to other word lines (non-selected word lines WLusel).

In addition, while maintaining the voltages applied to the selected select gate line SGDsel and the select gate line SGS, for example, the voltage Vss is applied from the voltage generation circuit 43 to the non-selected select gate line SGDusel via the row decoder 130. Accordingly, the select transistor ST1 provided in the selected string unit SU remains on, but the select transistor ST1 provided in the non-selected string unit SU enters an off state. It is noted that, regardless of whether it is the selected string unit SU or the non-selected string unit SU, the select transistor ST2 provided in the selected block BLK enters an on state.

Accordingly, in the NAND string NS provided in the non-selected string unit SU, since at least the select transistor ST1 enters an off state, no current path is formed. On the other hand, in the NAND string NS provided in the selected string unit SU, the current path is formed or not formed according to the relationship between the read voltage Vr applied to the selected word line WLsel and the threshold voltage of the memory cell transistor MT.

The sense amplifier 120 applies the voltage to the bit line BL connected to the selected NAND string NS. In this status, the sense amplifier 120 performs the data reading based on the value of the current flowing through the bit line BL. Specifically, it is determined whether the threshold voltage of the memory cell transistor MT, which is the target of the read operation, is higher than the read voltage applied to the memory cell transistor MT. It is noted that the data reading may be performed not based on the value of the current flowing through the bit line BL but based on a temporal change in the potential on the bit line BL. In the latter case, the bit line BL is precharged so as to be at the predetermined potential in advance.

The verify operation described above is also performed similarly to the read operation described above. In the verify operation, the verify voltage, for example, similarly to VfyA is applied from the voltage generation circuit 43 via the row decoder 130 to the word line WL connected to the memory cell transistor MT, which is target of verification.

It is noted that the operation of applying the voltage of 5 V to the selected select gate line SGDsel and the non-selected select gate line SGDusel in the initial stage of the program operation described above may be omitted. Similarly, in some cases, the operations of applying the voltage of 5 V to the non-selected select gate line SGDusel and applying the read pass voltage VPASS_READ to the selected word line WLsel in the initial stage of the read operation (verify operation) described above may be omitted.

The flow of signals transmitted and received between the semiconductor storage device 2 and the memory controller 1 during the write operation will be described. In the following, the example will be described in which the target of the write operation is the plane PL1, but the same applies to the case of the plane PL2.

FIG. 10 illustrates examples of various signals transmitted and received between the semiconductor storage device 2 and the memory controller 1 in the configuration according to this embodiment.

During the write operation, a signal including “80 h” and a plurality of “ADD” is sequentially input as the signal DQ<7:0> from the memory controller 1 toward the semiconductor storage device 2. “The 80 h” is a command for allowing the memory cell array 110 to execute data writing. “The ADD” is a signal that designates an address which is a writing destination of the data.

After transmitting the address to the semiconductor storage device 2 as described above, the memory controller 1 transmits the data to be written to the semiconductor storage device 2. The memory controller 1 inputs the write data to the semiconductor storage device 2 by switching each of the signals DQ<7:0> between the H level and the L level in accordance with the write data. In FIG. 10, each of the write data input as a signal DQ<7:0> is illustrated as a “D”.

These write data are acquired by the semiconductor storage device 2 at the rising and falling timings of the data strobe signal DQS input from the memory controller 1 and are temporarily stored in the latch circuit provided in the semiconductor storage device 2. After a series of the write data is input to the semiconductor storage device 2, “the 10 h” is input as the signal DQ<7:0> from the memory controller 1 toward the semiconductor storage device 2. Thereafter, the program operation and verify operation described above are performed, and data is actually written into the memory cell array 110.

Each semiconductor storage device 2 as the signal DQ<7:0> corresponding to each write data from the memory controller 1 corresponds to “the first toggle signal” in this embodiment. The portion of the semiconductor storage device 2 that receives the first toggle signal, that is, each of the plurality of pads provided in the input/output pad group 31 corresponds to “the receiving unit” (or “receive unit”) in this embodiment.

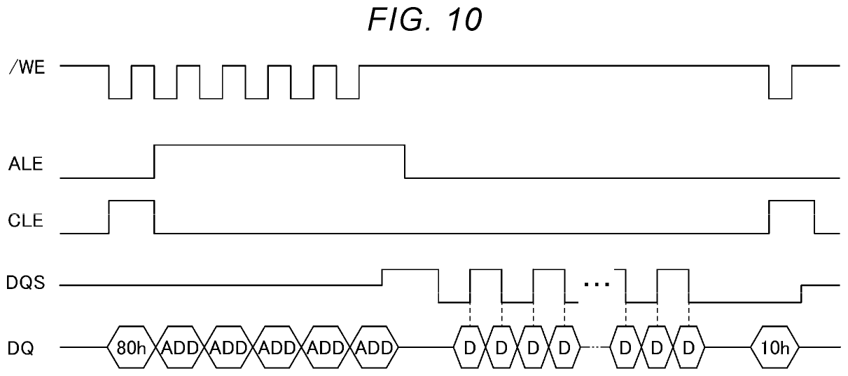

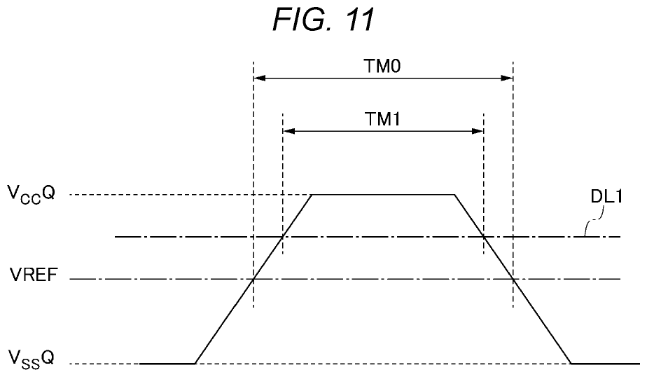

The overview of the method by which the semiconductor storage device 2 acquires data based on the first toggle signal will be described with reference to FIG. 11. FIG. 11 illustrates an example of a waveform of the first toggle signal input from the memory controller 1 to the semiconductor storage device 2, and namely, an example of a waveform of a signal input to one pad among the signals DQ<7:0> is illustrated. In the example of FIG. 11, the first toggle signal is a signal that switches between VccQ, which is an H level, and VssQ, which is a L level, according to the write data.

In order to determine whether the first toggle signal input from the memory controller 1 is currently at any one of the H level and the L level, the semiconductor storage device 2 compares the first toggle signal with a reference potential VREF. The reference potential VREF is set, for example, as an intermediate potential between the H level and the L level. When the VccQ at the H level is 1.2 V, the reference potential VREF is set to 0.6 V. When the first toggle signal is higher than the reference potential VREF, the semiconductor storage device 2 determines that the first toggle signal is at the H level. When the first toggle signal is lower than the reference potential VREF, the semiconductor storage device 2 determines that the first toggle signal is at the L level.

For example, when the first toggle signal at the H level is input, in order for the semiconductor storage device 2 to accurately acquire the write data corresponding to the H level, the acquisition of the write data needs to be performed at any timing during the period TM0 from the time when the first toggle signal exceeds the reference potential VREF until the potential becomes lower than the reference potential VREF. In other words, the timing at which the data strobe signal DQS rises or falls needs to fall within the period TM0.

The same applies to the case where the first toggle signal at the L level is input. Therefore, it is considered that, when the reference potential VREF is always set as an exactly intermediate potential between the H level and the L level, the length of the period during which the acquisition of the write data needs to be performed can be ensured to be the maximum extent.

However, in reality, the reference potential VREF may shift due to variations in circuit configuration. For example, as illustrated by a dotted line DL1 in FIG. 11, the actual reference potential VREF may be closer to the H level. In this case, the reception of the write data needs to be performed at a strict timing during the period TM1, which is shorter than the period TM0.

In addition, in some cases, even when the value of the reference potential VREF is correct, for example, the same determination as when the reference potential VREF is the same as when the dotted line DL1 in FIG. 11 may be performed due to variation in a circuit (comparison circuit 50 described later) for comparing the magnitude relationship between the first toggle signal and the reference potential VREF. In this case as well, the timing of receiving the write data becomes severe, as described above.

In recent years, the operating speed of the semiconductor storage device 2 has been improved, and there is a demand for the faster switching cycle of the first toggle signal. For this reason, it is considered that the completion of the reception of the write data during the narrowed period TM1 as described above becomes increasingly difficult.

Therefore, in this embodiment, the above-described problem is solved by devising the configuration of the input/output circuit 21 that receives the first toggle signal.

The configuration of the input/output circuit 21 and the like according to this embodiment will be described. FIG. 12 illustrates a portion of the configuration of the input/output pad group 31 and the input/output circuit 21 according to this embodiment as a schematic circuit diagram.

As described above, a plurality of pads for receiving the signal DQ<7:0> as a first toggle signal are provided to the input/output pad group 31. In FIG. 12, among a plurality of these pads, only two of these pads 311 and 312, are illustrated. The Pad 311 is a pad that receives a signal DQ<0>, and the pad 312 is a pad that receives a signal DQ<1>. The first toggle signal received by the pad 311 is illustrated as “DQ0” in FIG. 12. The first toggle signal received by the pad 312 is illustrated as “DQ1” in FIG. 12.

A plurality of the comparison circuits 50 corresponding to the respective pads 311 and the like is provided to the input/output circuit 21. FIG. 12 illustrates only two comparison circuits 50 connected to the pads 311 and 312. The configurations of the respective comparison circuits 50 are the same.

The comparison circuit 50 has a first input unit 51, a second input unit 52, and an output unit 53.

The first input unit 51 is a portion to which the first toggle signal (DQ0 or the like) is input. The signal lines extending from the pads 311 and the like of the input/output pad group 31 are connected to the first input unit 51.

The second input unit 52 is a portion to which the reference potential VREF is input. The reference potential VREF is generated by the voltage generation circuit 43 (not illustrated) in FIG. 12 and is input from the voltage generation circuit 43 to the second input unit 52. It is noted that, although the reference potential VREF is a potential that is common to all the comparison circuits 50 provided in the input/output circuit 21, the reference potential VREF may be the potential individually adjusted in advance in the respective comparison circuits 50

The output unit 53 is a unit that outputs the second toggle signal. “The second toggle signal” is a signal generated and output by the comparison circuit 50 as a signal that switches according to the magnitude relationship of the first toggle signal with respect to the reference potential VREF. In FIG. 12, the second toggle signal output from the comparison circuit 50 connected to the pad 311 is illustrated as “DQ0_C”, and the second toggle signal output from the comparison circuit 50 connected to the pad 312 is illustrated as “DQ1_C”. Each second toggle signal is transmitted as a signal indicating the write data received from the memory controller 1 to, for example, the latch circuit SD.

When the input first toggle signal (DQ0 or the like) is at a level higher than that of the reference potential VREF, the comparison circuit 50 outputs the second toggle signal ((DQ0_C or the like)) as a L level from the output unit 53. At other times, the comparison circuit 50 outputs the second toggle signal (DQ0_C or the like) from the output unit 53 as an H level.

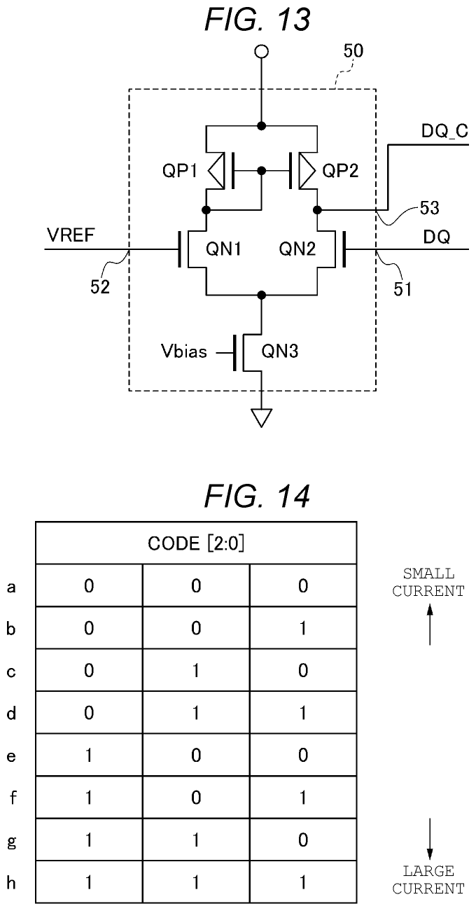

As a configuration of the comparison circuit 50 that operates in this manner, various known configurations can be adopted, as illustrated in, for example, FIG. 13. The comparison circuit 50 illustrated in FIG. 13 includes PMOS transistors QP1, QP2 and NMOS transistors QN1, QN2, and QN3. The PMOS transistors QP1 and QP2 have the sources connected to a power supply voltage terminal. The PMOS transistor QP1 is diode-connected, and the gate is further connected to the gate of the PMOS transistor QP2.

The drains of the NMOS transistors QN1 and QN2 are connected to the drains of PMOS transistors QP1 and QP2, respectively. The reference potential VREF is input to the gate of the NMOS transistor QN1 via the second input unit 52. The first toggle signal DQ (DQ0 or the like in the example of FIG. 12) is input to the gate of the NMOS transistor QN2 via the first input unit 51. The NMOS transistor QN3 is connected between the sources of the NMOS transistors QN1 and QN2 and the ground terminal, and a bias voltage Vbias is applied to each of the gates.

The signal indicating the potential of the portion connecting the drain of the NMOS transistor QN2 and the drain of the PMOS transistor QP2 is output as a second toggle signal DQ_C (DQ0_C or the like in the example of FIG. 12) from the output unit 53 to the outside of the comparison circuit 50.

Returning to FIG. 12, the explanation will be continued. The input/output circuit 21 is provided with a plurality of current sources 61 corresponding to the respective comparison circuits 50. The current source 61 is a variable current source electrically connected to the output unit 53. Specifically, the current source 61 is configured to be able to adjust the magnitude of the current flowing toward the ground line connected between the signal line extending from the output unit 53 and the ground line. The magnitude of the current output from the current source 61 is adjusted by the correction code (CODE) transmitted from the sequencer 41.

The correction code is, for example, a 3-bit digital signal as illustrated in each row of FIG. 14. The sequencer 41 adjusts the magnitude of the current drawn from the output unit 53 side by the current source 61 by transmitting the correction code illustrated in any of the rows a to h in FIG. 14 to the current source 61. In the example of FIG. 14, the current is the smallest when the correction code in the row a is transmitted, and the current is the largest when the correction code in the row h is transmitted. In this manner, the corresponding relationship between the CODE and the output current is set in advance so that the larger the correction code (CODE) is, the larger the output current of the current source 61 is.

The current source 61 in this embodiment is configured so that three current sources (not illustrated) having different current values are connected in parallel to each other and so that ON/OFF of each current source is switched individually according to the value of each of the upper bit, the middle bit, and the lower bit of the correction code. For example, when the correction code for the row g is transmitted, the current sources corresponding to the upper bit and the middle bit enter an on state, and the current sources corresponding to the lower bits enter an off state. By such a method, the magnitude of the current drawn from the output unit 53 side by the current source 61 can be adjusted in a stepwise manner in accordance with the correction code in each row in FIG. 14.

By adjusting the magnitude of the current drawn from the output unit 53 side by the current source 61, the sequencer 41 can change the waveform of the first toggle signal (DQ0 or the like) output from the output unit 53 similarly to the case of changing the reference potential VREF.

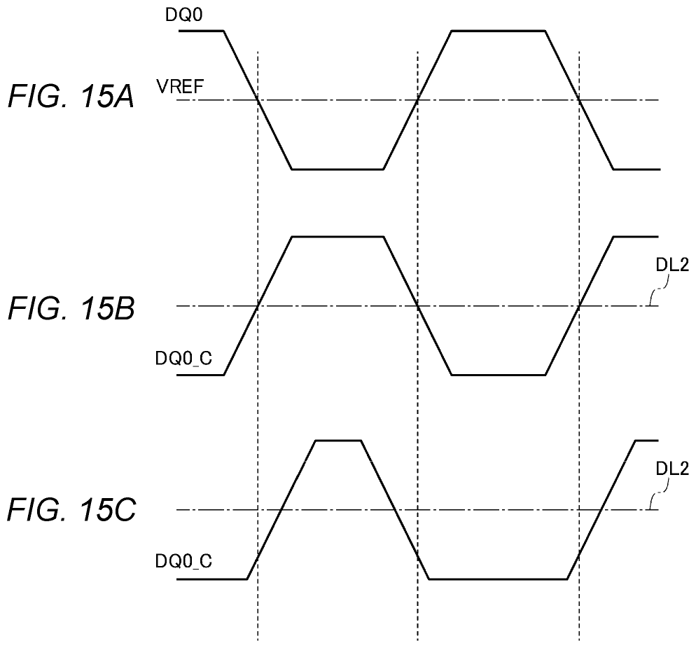

FIG. 15A illustrates an example of the waveform of the first toggle signal DQ0 input to the first input unit 51. In this example, the reference potential VREF is set to be intermediate between the H level and the L level.

FIG. 15B illustrates an example of a waveform of the second toggle signal DQ0_C output from the output unit 53. In this example, the second toggle signal DQ0_C is output with an ideal duty according to the magnitude relationship between the first toggle signal DQ0 and the reference potential VREF. It is noted that the dotted line DL2 illustrated in FIG. 15B indicates the intermediate potential of the second toggle signal DQ0_C that changes between the H level and the L level. In the example of FIG. 15B, the timing at which the first toggle signal DQ0 crosses the reference potential VREF and the timing at which the second toggle signal DQ0_C crosses the dotted line DL2 match each other.

When the current drawn from the output unit 53 side by the current source 61 is increased from the status illustrated in FIG. 15B, the second toggle signal DQ0_C output from the output unit 53 changes as illustrated in FIG. 15C. At this time, the timing at which the second toggle signal DQ0_C increases from the L level and crosses the intermediate dotted line DL2 is later than that in FIG. 15B. In addition, the timing at which the second toggle signal DQ0_C decreases from the H level and crosses the intermediate dotted line DL2 is earlier than in FIG. 15B.

The change in the second toggle signal DQ0_C as illustrated in FIG. 15C is substantially the same as the change in the second toggle signal DQ0_C when the reference potential VREF is decreased from the status in FIG. 15A. Therefore, by increasing the current output from the current source 61, the sequencer 41 can adjust the waveform of the second toggle signal DQ0_C so as to become substantially the same as when the reference potential VREF is decreased.

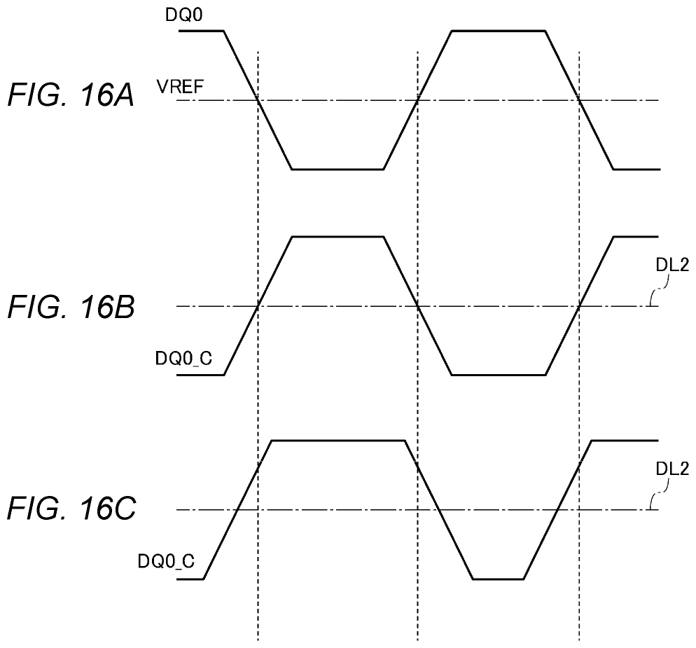

The waveforms illustrated in FIGS. 16A and 16B are the same as those illustrated in FIGS. 15A and 15B, respectively. When the current drawn from the output unit 53 by the current source 61 decreases from the status illustrated in FIG. 16B, the second toggle signal DQ0_C output from the output unit 53 changes as illustrated in FIG. 16C. At this time, the timing at which the second toggle signal DQ0_C increases from the L level and crosses the intermediate dotted line DL2 is earlier than that in FIG. 16B. Furthermore, the timing at which the second toggle signal DQ0_C decreases from the H level and crosses the intermediate dotted line DL2 is later than that in FIG. 16B.

The change in the second toggle signal DQ0_C as illustrated in FIG. 16C is substantially the same as a change in the second toggle signal DQ0_C when the reference potential VREF is increased from the status in FIG. 16A. Therefore, the sequencer 41 can adjust the waveform of the second toggle signal DQ0_C so as to be substantially the same as the case where the reference potential VREF is increased, by reducing the current output from the current source 61.

It is noted that it is difficult for the sequencer 41 and the like of the semiconductor storage device 2 by itself to determine how much the reference potential VREF needs to be set, in other words, how much the current drawn from the output unit 53 by the current source 61 needs to be set. For this reason, this determination is performed outside the semiconductor storage device 2, for example, by the memory controller 1.

For example, the memory controller 1 allows the semiconductor storage device 2 to transmit the control signal and allows the sequencer 41 to generate the correction code so that the output current of the current source 61 has a magnitude corresponding to the control signal. Subsequently, the memory controller 1 transmits predetermined test data to the semiconductor storage device 2 to perform the write operation and, after that, allows the semiconductor storage device 2 to perform the read operation regarding the same test data. At this time, when the data read from the semiconductor storage device 2 does not match the previous test data, similarly to the case where, for example, the TM1 becomes too short in the example illustrated in FIG. 11, it can be estimated that the output current of source 61 is not appropriate. On the other hand, when the data read from the semiconductor storage device 2 matches the test data, it can be estimated that the output current of the current source 61 is appropriate. The memory controller 1 sets the output current of the current source 61 to an appropriate value by alternately repeating changing the setting of the output current of the current source 61 and the writing and reading of the test data, and after that, accurately performs the write operation of the semiconductor storage device 2.

In order to implement the above-described operations, the sequencer 41 of the semiconductor storage device 2 according to this embodiment has a function of adjusting the current output from the current source 61 according to the control signal input from the outside such as the memory controller 1. The control signal may be input to the semiconductor storage device 2 through the input/output pad group 31 by, for example, a SetFeature function. The sequencer 41 having such a function corresponds to “the adjustment unit” in this embodiment. A portion different from the sequencer 41 may have the function of adjusting the current output from the current source 61.

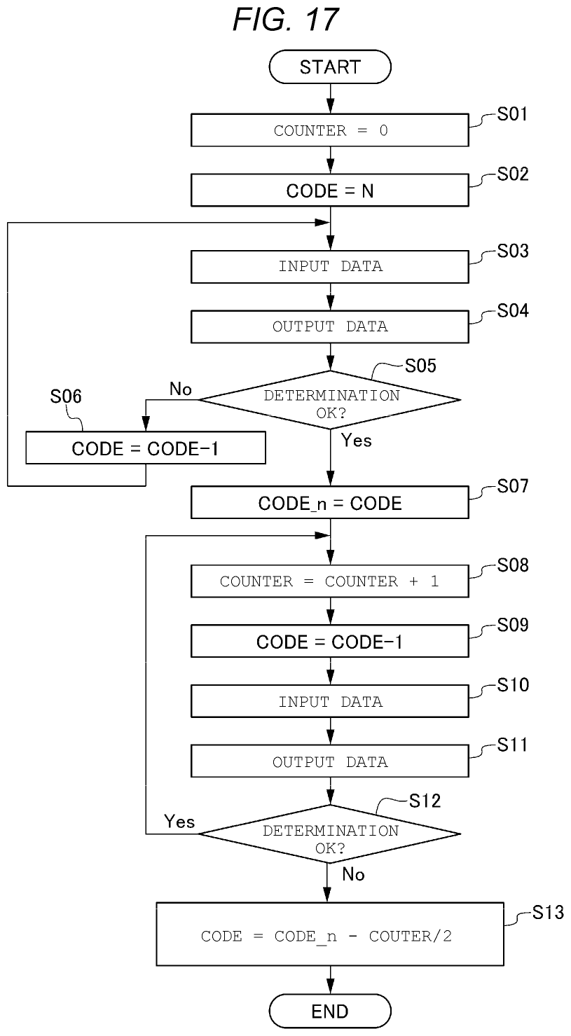

The specific flow of processes executed by the memory controller 1 in order to set the current output from the current source 61 will be described with reference to FIG. 17. A series of processes illustrated in FIG. 17 is started, for example, at timing such as when the memory controller 1 is activated.

In the first step S01, the value of the counter is set to 0. This “counter” is an internal variable for recording the number of consecutive Yes determinations in step S05 and step S12, which will be described later.

In step S02 following step S01, N is set as a value of the CODE. “The CODE” referred herein is a variable that takes one of the values of the CODE[2:0] illustrated in FIG. 14, and is transmitted as a control signal for adjusting the current output from the current source 61 to the semiconductor storage device 2. The above-mentioned “N” is a maximum value that the CODE can take. In the example of FIG. 14, “111” in the row h is set as a value of N. The CODE set in step S02 is immediately transmitted as a control signal to the semiconductor storage device 2. The sequencer 41 uses the CODE received as a control signal as a correction code for adjusting the current value of the current source 61. That is, the sequencer 41 adjusts the current output from the current source 61 so that the current corresponds to the control signal.

In step S03 following step S02, predetermined write data is input to the semiconductor storage device 2, and the semiconductor storage device 2 is allowed to perform the write operation. “The predetermined write data” refers to test data described above.

In step S04 following step S03, the semiconductor storage device 2 is allowed to perform the read operation, and the read data is output to the memory controller 1. The data read herein is the write data stored in the semiconductor storage device 2 in step S03.

In step S05 following step S04, it is determined whether the value of the CODE transmitted to the semiconductor storage device 2 is appropriate. When the data input to the semiconductor storage device 2 in step S03 and the data output from the semiconductor storage device 2 in step S04 do not match each other, it is determined that the value of the CODE is inappropriate. In this case, the process proceeds to step S06. In step S06, the value of the CODE is decremented by 1. The updated CODE is immediately transmitted as a control signal to the semiconductor storage device 2. Thereafter, the processes of step S03 and following steps are executed again.

When it is determined that the value of the CODE is appropriate in step S05, that is, when the data input to the semiconductor storage device 2 in step S03 and the data output from the semiconductor storage device 2 in step S04 match each other, the process proceeds to step S07. In step S07, a value of a CODE_n is set to the current value of the CODE. “The CODE_n” is an internal variable for storing the value of the CODE at the time when it is first determined Yes in step S05 in the case where the value of the CODE is changed from N as described above.

In step S08 following step S07, the value of the counter is incremented by one. In step S09 following step S08, the value of the CODE is decremented by 1, similarly to step S06. The updated CODE is immediately transmitted as a control signal to the semiconductor storage device 2.

In step S10 following step S09, predetermined write data is input to the semiconductor storage device 2, and the semiconductor storage device 2 is allowed to perform the write operation, similarly to step S03. In step S11 following step S10, similarly to step S04, the semiconductor storage device 2 is allowed to perform the read operation, and the read data is output to the memory controller 1. In step S12 following step S11, similarly to step S05, it is determined whether the value of the CODE transmitted to the semiconductor storage device 2 is appropriate.

When the data input to the semiconductor storage device 2 in step S10 and the data output from the semiconductor storage device 2 in step S11 match each other, the processes of step S08 and following steps are executed again.

When the decrement of the CODE in step S09 is repeated, the value of the CODE will deviate from an appropriate range. That is, in the determination in step S12, the data input to the semiconductor storage device 2 in step S10 and the data output from the semiconductor storage device 2 in step S11 do not match each other. In this case, the process proceeds to step S13.

In step S13, the value obtained by subtracting ½ of the counter from the value of the CODE_n is set as a final value of the CODE. The CODE set in this manner is an intermediate value among the plurality of CODEs determined to be appropriate in step S05 and step S12. The CODE set in step S13 is immediately transmitted as a control signal to the semiconductor storage device 2.

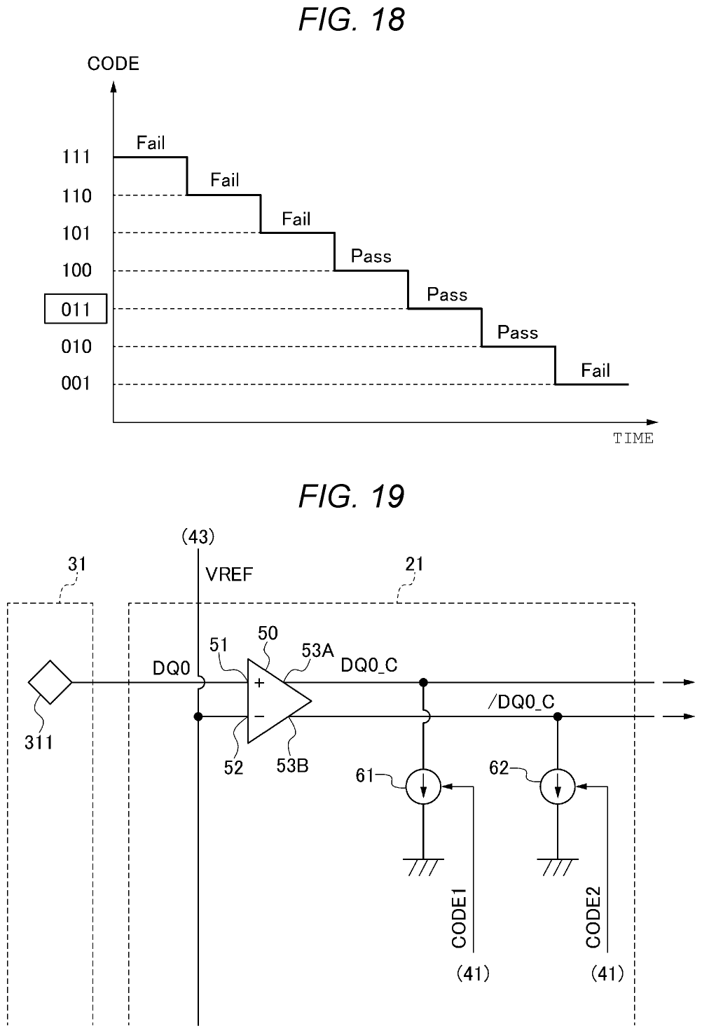

FIG. 18 schematically illustrates a CODE setting method as described above. In the example of FIG. 18, after the value of the CODE is set to 111 (N described above), the value of the CODE is decremented. In FIG. 18, character strings “Fail” and “Pass” indicate the determination results in step S05 and step S12 for each value of the CODE. In the example of FIG. 18, the determination result becomes Pass for the first time when the value of the CODE becomes 100. Even when the value of the CODE is 011 or 010, the determination result becomes Pass, but when the value of the CODE is decremented to 001, the determination result becomes Fail again. In this case, the value of the CODE will be set to 011, which is the intermediate value among the three cases of becoming Pass. With this method, the most appropriate value as CODE can be set.

As described above, the semiconductor storage device 2 according to this embodiment includes the variable current source 61 connected to the comparison circuit 50 and the sequencer 41 adjusting the current output from the current source 61 based on the control signal input from the outside. With this configuration, even when the reference potential VREF deviates from the appropriate value, the duty of the second toggle signal (DQ0_C or the like) output from the output unit 53 of the comparison circuit 50 can be adjusted, and thus the write data can be accurately acquired.

It is noted that the problem is that the duty of the second toggle signal causes the reference potential VREF to be variated due to the variations in the circuit configuration and additionally due the variations in the comparison circuit 50. For example, when there are variations in the transistors constituting the comparison circuit 50 illustrated in FIG. 13, even in the case where the value of the reference potential VREF is correct, the duty of the second toggle signal changes similarly to the case where the reference potential VREF is variated. In any case, according to the semiconductor storage device 2 according to this embodiment, the duty of the second toggle signal can be adjusted to be appropriate by using the current from the current source 61.

As described with reference to FIG. 12, in this embodiment, the comparison circuit 50 and the current source 61 are individually provided for each of the pads 311 and the like provided in the input/output pad group 31. The sequencer 41, which is an adjustment unit can individually adjust the current output from each of the plurality current sources 61. For this reason, when the CODE corresponding to each of the plurality of current sources 61 is individually transmitted as a control signal from the memory controller 1, the appropriate current value of the current source 61 can be adjusted individually for each pad of the input/output pad group 31.

In recent years, in some cases, in order to cope with the increase in speed of the first toggle signal or the like, it has been considered to use a potential lower than the VccQ in FIG. 11 as an H level of the first toggle signal. In other words, it is also considered to narrow the amplitude of the first toggle signal. In this case, it is expected that the need to be capable of individually adjusting the duty of the second toggle signal for each pad provided in the input/output pad group 31 will become further increased. According to the semiconductor storage device 2 according to this embodiment, such requests for individual adjustment can be easily coped with.

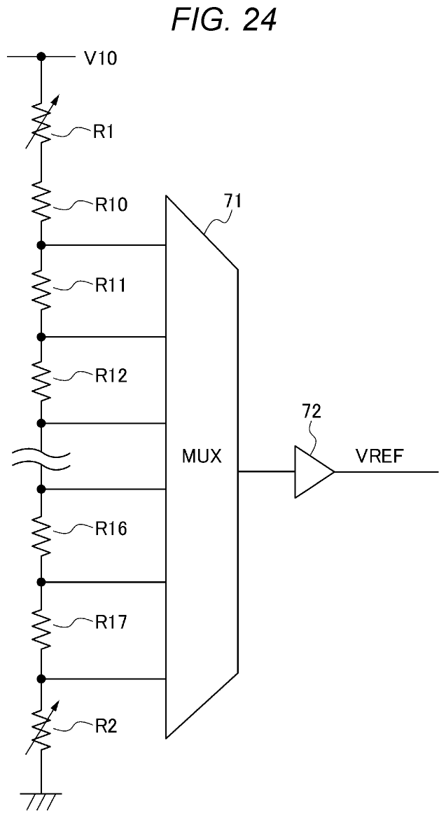

It is noted that as measures to allow the duty of the second toggle signal to be appropriate, the reference potential VREF can be adjusted by the sequencer 41 by providing, for example, a ladder resistance circuit as illustrated in FIG. 24 on the semiconductor 2.

This ladder resistance circuit includes a plurality of resistors R10 to R17 disposed to be aligned in series between the power supply line maintained at a predetermined potential V10 and the ground line. A variable resistor R1 is disposed between the resistor R10 and the power supply line, and a variable resistor R2 is disposed between the resistor R17 and the ground line. Among the resistors R10 to R17, the respective potentials of the portions between adjacent resistors are input to a multiplexer 71. The multiplexer 71 inputs one of the plurality of input potentials to the amplifier 72 in accordance with the signals from the sequencer 41. The amplifier 72 amplifies the potential and inputs the potential as the reference potential VREF to the second input unit 52 of the comparison circuit 50. By adjusting the reference potential VREF by using the above-described configuration, the length of the period TM1 is changed, and the duty of the second toggle signal can be appropriately adjusted.

However, similarly to this embodiment, in order to be able to individually adjust the duty of the second toggle signal for each pad provided in the input/output pad group 31, the same number of ladder resistance circuits as pads illustrated in FIG. 24 needs to be provided. The ladder resistance circuit of FIG. 24 is relatively large. For this reason, when the same number of ladder resistance circuits as the number of pads as illustrated in FIG. 24 is provided, since the space for disposing the ladder resistance circuits in the semiconductor storage device 2 becomes too increased, the providing is not practical.

In contrast, in this embodiment, there is no need to use the ladder resistance circuit, and only the relatively small current source 61 is provided, and thus the duty of the second toggle signal can be individually adjusted for each pad provided in the input/output pad group 31.

It is noted that the current sources 61 connected to each comparison circuit 50 may be provided in a manner different from that illustrated in FIG. 12. For example, the current source 61 may be provided at the position in the middle of the wiring that connects the power supply line maintained at the predetermined potential such as VccQ and the signal line extending from the output unit 53 of the comparison circuit 50. In this case, the sequencer 41, which is an adjustment unit adjusts the magnitude of the current supplied from the current source 61 to the signal line extending from the output unit 53.

In the example described above, the CODE that directly designates the current output from the current source 61 is used as a control signal transmitted from the memory controller 1 to the semiconductor storage device 2. However, the control signal from the memory controller 1 may be different from such a signal. For example, the signal indicating the value of the reference potential VREF to be set may be transmitted as a control signal to the semiconductor storage device 2. In this case, the sequencer 41 may generate the correction code corresponding to the control signal (value of the reference potential VREF) and adjust the current output from the current source 61, by referring to a map created in advance.

The second embodiment will be described. In the following, points different from the first embodiment will be mainly described, and description of points common to the first embodiment will be omitted as appropriate. This embodiment is different from the first embodiment in the configuration of the input/output circuit 21.

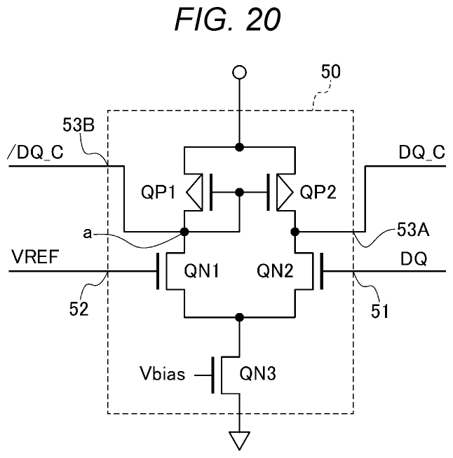

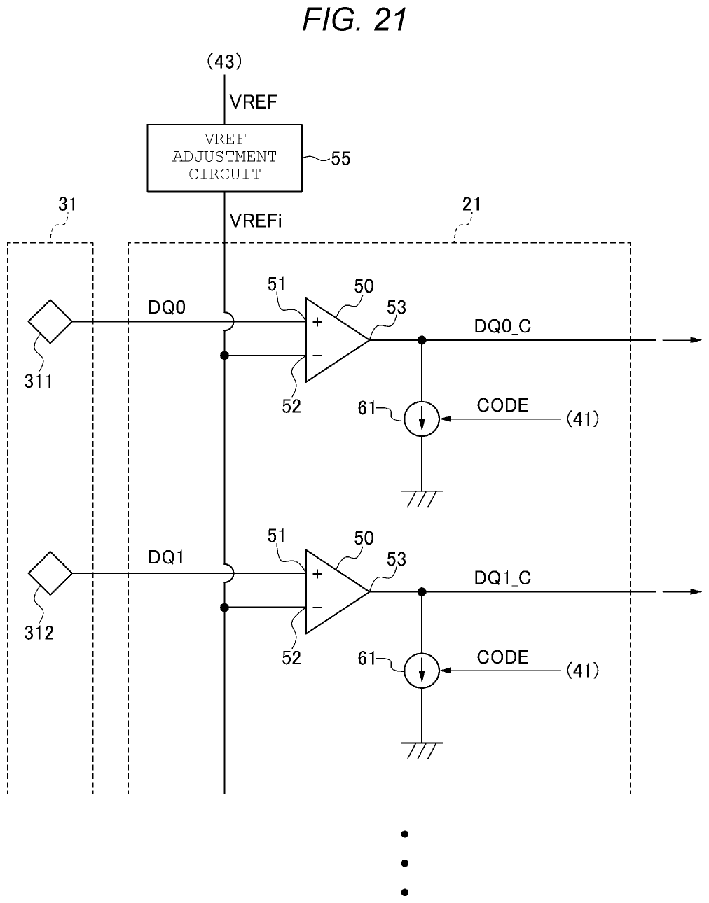

FIG. 19 illustrates a configuration of the input/output circuit 21 according to this embodiment as a schematic circuit diagram. The comparison circuit 50 of this embodiment has two output units 53. One output unit 53 will be referred to as “a first output unit 53A” hereinafter. The other output unit 53 will be referred to as “a second output unit 53B” hereinafter. The first output unit 53A is a unit that outputs the second toggle signal (DQ0_C or the like) similarly to the output unit 53 of the first embodiment. The second output unit 53B is a unit that outputs the complementary signal to the second toggle signal. The complementary signal output from the second output unit 53B will be expressed as “/DQ0_C”, “/DQ_C”, or the like hereinafter. The configuration of the comparison circuit 50 is as illustrated in, for example, FIG. 20. In this example, the connection portion between the drain of the NMOS transistor QN1 and the drain of the PMOS transistor QP1 (the portion labeled “a” in FIG. 20) is connected to the second output unit 53B, and the second embodiment is different from the first embodiment in this point.

As illustrated in FIG. 19, the input/output circuit 21 of this embodiment is provided with current sources 61 and 62 corresponding to the comparison circuit 50. Each of the other input/output circuits 21 not illustrated in FIG. 19 is also individually provided with a pair of current sources 61 and 62.

Similarly to the first embodiment, the current source 61 is a variable current source electrically connected to the first output unit 53A. Specifically, the current source 61 is configured so that the signal line extending from the first output unit 53A and the ground line and so that the magnitude of the current flowing toward the ground line side can be adjusted. The magnitude of the current output from the current source 61 is adjusted by the correction code (CODE1) transmitted from the sequencer 41. The current source 61 corresponds to a “first current source” in this embodiment.

The current source 62 is a variable current source electrically connected to the second output unit 53B. Specifically, the current source 62 is configured to be connected between the signal line extending from the second output unit 53B and the ground line, so that the magnitude of the current flowing toward the ground line side can be adjusted. The magnitude of the current output from the current source 62 is adjusted by the correction code (CODE2) transmitted from the sequencer 41. The current source 62 corresponds to a “second current source” in this embodiment.

Each of the correction codes (CODE1, CODE2) is similar to the CODE of the first embodiment, and is, for example, a 3-bit digital signal as illustrated in each row of FIG. 14. The sequencer 41 can individually transmit each of the CODE1 and the CODE2. In other words, the sequencer 41 can independently adjust the magnitude of the current drawn from the first output unit 53A side by the current source 61 and the magnitude of the current drawn from the second output unit 53B side by the current source 62. In addition, the sequencer 41 can adjust the currents output from the current source 61 and the current source 62 for each comparison circuit 50 individually (that is, independently of each other).

With such a configuration, the duty of the second toggle signal can be adjusted by the memory controller 1 and sequencer 41 performing the same process as described in the first embodiment. It is noted that when increasing the current output from the current source 61, the sequencer 41 may decrease the current output from the current source 62 by only the same extent. Furthermore, when decreasing the current output from the current source 61, the sequencer 41 may increase the current output from the current source 62 by the same extent.

The number and connection positions of the current sources 61 and the like can be changed as appropriate from the first embodiment, similarly to this embodiment. For example, in the configuration in which the second output unit 53B is not provided, similarly to the comparison circuit 50 (FIG. 13) of the first embodiment, the current from the current source 62 applied to the portion corresponding to “a” in FIG. 20 may also be provided in the same manner. In this case, the current source connected to the comparison circuit 50 may be only the current source 62 as described above, or may additionally include the current source 61 similar to the first embodiment.

Also in this embodiment, the current sources 61 and 62 connected to each comparison circuit 50 may be provided in the manner different from that in FIG. 19. For example, the current source 61 may be provided at the position in the middle of the wiring that connects the power supply line maintained at the predetermined potential such as VccQ and the signal line extending from the first output unit 53A of the comparison circuit 50. In addition, the current source 62 may be provided at the position in the middle of the wiring that connects the power supply line maintained at the predetermined potential such as VccQ and the signal line extending from the second output unit 53B of the comparison circuit 50.

The third embodiment will be described. In the following, points different from the first embodiment will be mainly described, and the description of points common to the first embodiment will be omitted as appropriate. A configuration of the input/output circuit 21 according to this embodiment is almost the same as the configuration in the first embodiment, as illustrated in FIG. 21. In this embodiment, the second input units 52 of the respective comparison circuits 50 are connected to each other, and the common reference potential VREF (specifically, a reference potential VREFi to be described later) is input to all the comparison circuits 50.

This embodiment further includes a VREF adjustment circuit 55 for adjusting the reference potential VREF. The VREF adjustment circuit 55 is a circuit configured to adjust the reference potential VREF generated by the voltage generation circuit 43 and, after that, input the reference potential VREF to each comparison circuit 50. The adjustment of the reference potential VREF by the VREF adjustment circuit 55 is controlled by the sequencer 41. Although the specific configuration of the VREF adjustment circuit 55 is not particularly limited, for example, the configuration of the ladder resistance circuit as illustrated in FIG. 24 can be adopted. The sequencer 41 of this embodiment controls the operation of the VREF adjustment circuit 55 so as to change the reference potential VREF according to the control signal from the memory controller 1. The reference potential VREF adjusted by the VREF adjustment circuit 55, that is, the adjusted reference potential VREF input to each comparison circuit 50, is also referred to as “a reference potential VREFi” hereinafter.

As described above, in this embodiment, two types of control signals are transmitted from the memory controller 1 to the semiconductor storage device 2. One control signal is a signal for allowing the sequencer 41 to set the value of the reference potential VREFi after the change. This control signal is also referred to as “a first control signal” hereinafter. The other control signal is the same as the CODE in the first embodiment, and is a signal for allowing the sequencer 41 to set the output current of the current source 61. This control signal is also referred to as “a second control signal” hereinafter.

The memory controller 1 first transmits the first control signal to the semiconductor storage device 2 and allows the sequencer 41 to adjust the reference potential VREF. The adjusted reference potential VREFi is the reference potential VREFi that is commonly used in all the comparison circuits 50 provided in the input/output circuit 21, as described above. By adjusting the reference potential VREF, the duty of the second toggle signal output from each comparison circuit 50 is roughly adjusted.

Subsequently, the memory controller 1 transmits the second control signal to the semiconductor storage device 2 and allows the sequencer 41 to individually adjust the current output from each current source 61. Accordingly, the duty of the second toggle signal output from each comparison circuit 50 is individually and finely adjusted.

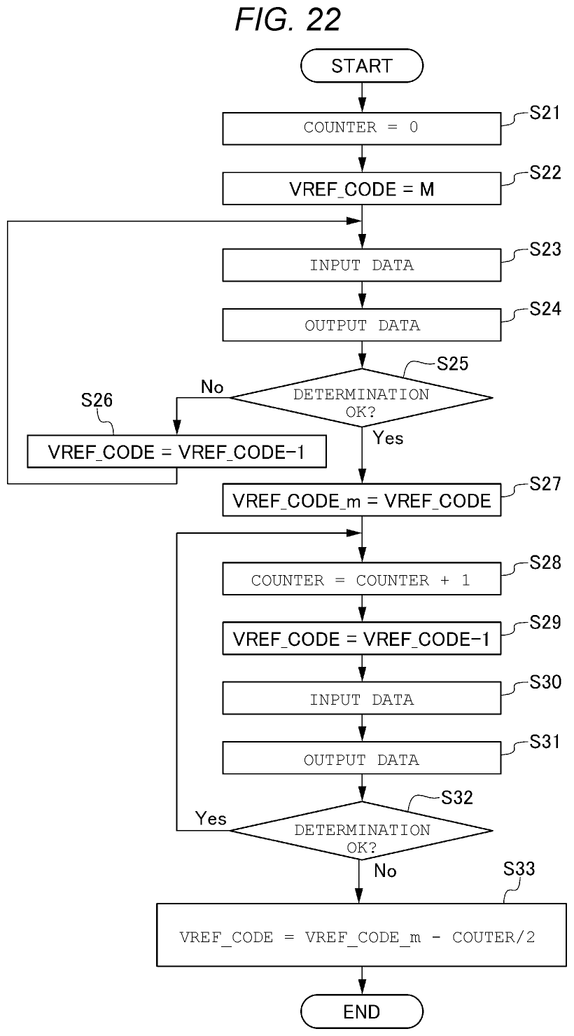

The specific flow of processes executed by the memory controller 1 to adjust the duty of the second toggle signal will be described with reference to FIG. 22. A series of processes illustrated in FIG. 22 is started at the timing such as when the memory controller 1 is activated, instead of a series of processes illustrated in FIG. 17.

In the first step S21, the value of the counter is set to 0. This “counter” is an internal variable for recording the number of consecutive Yes determinations in steps S25 and S32, which will be described later.

In step S22 following step S21, M is set as a value of a VREF_CODE. “The VREF_CODE” herein is a signal transmitted as the first control signal for adjusting the reference potential VREF to the semiconductor storage device 2. Similar to CODE[2:0] illustrated in FIG. 14, the corresponding relationship between the VREF_CODE and the reference potential VREFi is set in advance so that the larger the VREF_CODE is, the larger the reference potential VREFi after adjustment is set.

The above-mentioned “M” is the maximum value that the VREF_CODE can take. The VREF_CODE set in step S22 is immediately transmitted as a first control signal to the semiconductor storage device 2. The sequencer 41 uses the VREF_CODE received as a first control signal as a correction code for adjusting the reference potential VREF. That is, the sequencer 41 adjusts the reference potential VREF so that the reference potential VREFi has a magnitude corresponding to the VREF_CODE.

In step S23 following step S22, similarly to step S02 in FIG. 17, predetermined write data is input to the semiconductor storage device 2, and the semiconductor storage device 2 is allowed to perform the write operation. In step S24 following step S23, similarly to step S04 in FIG. 17, the semiconductor storage device 2 is allowed to perform the read operation, and thus the read data is output to the memory controller 1.

In step S25 following step S24, it is determined whether the value of the VREF_CODE transmitted to the semiconductor storage device 2 is appropriate. When the data input to the semiconductor storage device 2 in step S23 and the data output from the semiconductor storage device 2 in step S24 do not match each other, it is determined that the value of the VREF_CODE is inappropriate. In this case, the process proceeds to step S26. In step S26, the value of the VREF_CODE is decremented by 1. The updated VREF_CODE is immediately transmitted as the first control signal to the semiconductor storage device 2. Thereafter, the processes of step S23 and following steps are executed again.

When the value of the VREF_CODE is determined to be appropriate in step S25, that is, when the data input to the semiconductor storage device 2 in step S23 and the data output from the semiconductor storage device 2 in step S24 match each other, the process proceeds to step S27. In step S27, the value of the VREF_CODE_m is set as a current value of VREF_CODE. “The VREF_CODE_m” is an internal variable for storing the value of the VREF_CODE at the time when the first determination is Yes in step S25 in the case where the value of the VREF_CODE is changed from M as described above.

In step S28 following step S27, the value of the counter is incremented by one. In step S29 following step S28, the value of the VREF_CODE is decremented by 1, similarly to step S26. The updated VREF_CODE is immediately transmitted as the first control signal to the semiconductor storage device 2.

In step S30 following step S29, predetermined write data is input to the semiconductor storage device 2, similarly to step S23, and the semiconductor storage device 2 is allowed to perform the write operation. In step S31 following step S30, similarly to step S24, the semiconductor storage device 2 is allowed to perform the read operation and, thus the read data is output to the memory controller 1. In step S32 following step S31, similarly to step S25, it is determined whether the value of the VREF_CODE transmitted to the semiconductor storage device 2 is appropriate.

When the data input to the semiconductor storage device 2 in step S30 and the data output from the semiconductor storage device 2 in step S31 match each other, the processes from step S28 and following steps are executed again.

When the decrement of the VREF_CODE in step S29 is repeated, the value of the VREF_CODE will be out of the appropriate range. That is, in the determination in step S32, the data input to the semiconductor storage device 2 in step S30 and the data output from the semiconductor storage device 2 in step S31 do not match each other. In this case, the process proceeds to step S33.

In step S33, the value obtained by subtracting ½ of the counter from the value of the VREF_CODE_m is set as a final value of VREF_CODE. The VREF_CODE set in this manner that becomes an intermediate value among the plurality of VREF_CODEs determined to be appropriate in step S25 and step S32. The VREF_CODE set in step S33 is immediately transmitted as the first control signal to the semiconductor storage device 2.

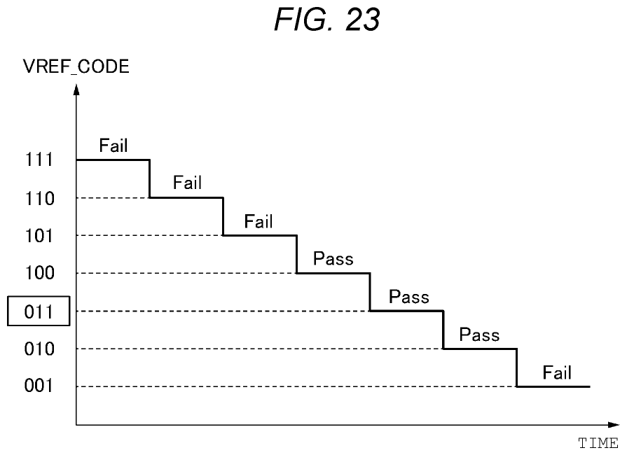

FIG. 23 schematically illustrates the VREF_CODE setting method as described above. In the example of FIG. 23, after a value of the VREF_CODE is set to 111 (M described above), the value of the VREF_CODE is decremented. The character strings “Fail” and “Pass” in FIG. 23 indicate the determination results in step S25 and step S32 for the respective values of the VREF_CODE. In the example of FIG. 23, the determination result becomes Pass for the first time when the value of the VREF_CODE becomes 100. Even when the value of the VREF_CODE is 011 or 010, the determination result is Pass, but when the value of the VREF_CODE is decremented to 001, the determination result is Fail again. In this case, the value of the VREF_CODE will be set to 011, which is the intermediate value among the three cases of Pass. In this manner, the most appropriate value can be set as a VREF_CODE.

As described above, the memory controller 1 allows the sequencer 41 to adjust the value of the reference potential VREF by executing a series of processes illustrated in FIG. 22. The sequencer 41 adjusts the value of the reference potential VREF to an optimum value based on the first control signal (VREF_CODE) from the memory controller 1.

After a series of processing illustrated in FIG. 22 is completed, the memory controller 1 individually adjusts the value of the current output from each current source 61 to the sequencer 41. Specifically, the memory controller 1 executes a series of processes illustrated in FIG. 17 for each of the plurality of comparison circuits 50 provided in the input/output circuit 21 and individually adjusts the value of the current output from the current source 61. Based on the second control signal (CODE) from the memory controller 1, the sequencer 41 adjusts the value of the current output from each current source 61 to the optimum value.

The corresponding relationship between the CODE and the output current of the current source 61 is as illustrated in, for example, FIG. 14. However, in many cases, an amount of variation in the output current when changing the value of the CODE by 1 is not constant. In other words, in many cases, it is difficult to ensure the linearity of the corresponding relationship between the CODE and output current.

Therefore, in this embodiment, as described above, after adjusting the reference potential VREF based on the first control signal (VREF_CODE), the adjustment of the output current from the current source 61 is performed based on the second control signal (CODE). By performing such two-stage adjustment, the adjustment width of the output current in each current source 61 can be decreased. For this reason, even when the linearity of the corresponding relationship between the CODE and the output current is not sufficiently ensured, the duty of the second toggle signal can be adjusted with high accuracy.

Also in this embodiment, the current sources 61 connected to each comparison circuit 50 may be provided in an aspect different from that in FIG. 21. For example, the current source 61 may be provided at a position in the middle of a wiring that connects the power supply line maintained at a predetermined potential such as VccQ and a signal line extending from the output unit 53 of the comparison circuit 50.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a receive unit configured to receive a first toggle signal;
a comparison circuit configured to generate and output a second toggle signal, wherein the second toggle signal switches based on a relationship of the first toggle signal relative to a reference potential;
a variable current source connected to the comparison circuit and configured to provide a current output; and
a sequencer configured to adjust the current output from the current source based on an input control signal.

2. The semiconductor storage device according to claim 1,
wherein the comparison circuit includes an output that outputs the second toggle signal, and
wherein the current source is connected to the output.

3. The semiconductor storage device according to claim 1,
wherein the comparison circuit includes:
a first output that outputs the second toggle signal; and
a second output that outputs a complementary signal of the second toggle signal, and
wherein a current source includes:
a first current source connected to the first output; and
a second current source connected to the second output.

4. The semiconductor storage device according to claim 1, comprising:
a plurality of the receive units, and
a plurality of the comparison circuits and a plurality of the current sources correspond to each of the plurality of the receive units.

5. The semiconductor storage device according to claim 4, wherein the sequencer is configured to individually adjust a current output from each of the current sources.

6. The semiconductor storage device according to claim 1,
wherein the input control signal includes a first control signal and a second control signal, and
wherein, after an adjustment of the reference potential based on the first control signal, the sequencer is configured to adjust the current output from the current source based on the second control signal.

7. The semiconductor storage device according to claim 6, comprising:
a plurality of the receive units,
a plurality of the comparison circuits and a plurality of the current sources correspond to each of the receive units, and
wherein the reference potential adjusted based on the first control signal is shared by the comparison circuits.

8. The semiconductor storage device according to claim 7, wherein the sequencer is configured to individually adjust the current output from each of the current sources.

9. A memory system, comprising:
a memory controller configured to provide a first toggle signal and a control signal; and
a plurality of semiconductor storage devices, each of the semiconductor storage devices comprising:
a receive unit configured to receive the first toggle signal from the memory controller;
a comparison circuit configured to generate and output a second toggle signal, wherein the second toggle signal switches based on a magnitude relationship of the first toggle signal relative to a reference potential;
a variable current source connected to the comparison circuit and configured to output a current; and
a sequencer configured to adjust the current output from the current source based on the control signal from the memory controller.

10. The memory system according to claim 9,
wherein the comparison circuit includes an output that outputs the second toggle signal, and
wherein the current source is connected to the output of the comparison circuit.

11. The memory system according to claim 9,
wherein the comparison circuit includes:
a first output that outputs the second toggle signal; and
a second output that outputs a complementary signal of the second toggle signal, and
wherein a current source includes:
a first current source connected to the first output of the comparison circuit; and
a second current source connected to the second output of the comparison circuit.

12. The memory system according to claim 9, comprising:
a plurality of the receive units, and
a plurality of the comparison circuits and a plurality of the current sources corresponding to each of the plurality of the receive units.

13. The memory system according to claim 9,
wherein the input control signal input includes a first control signal and a second control signal, and
wherein, after an adjustment of the reference potential based on the first control signal, the sequencer is configured to adjust the current output from the current source based on the second control signal.

14. The memory system according to claim 9,
wherein a plurality of the comparison circuits and a plurality of the current sources correspond to each of the receive units, and
wherein the reference potential adjusted based on the first control signal is shared by the comparison circuits.

15. A method, comprising:
receiving a first toggle signal;
generating and outputting a second toggle signal, wherein the second toggle signal switches based on a magnitude relationship of the first toggle signal relative to a reference potential; and
adjusting a current output from a current source based on an input control signal.

16. The method according to claim 15, further comprising:
adjusting the reference potential based on a first control signal of the input control signal, and
adjusting the current output from the current source based on a second control signal of the input control signal.
